(19) United States
(12) Patent Application Publication
(10) Pub. No.: US 2010/0277179 A1
(43) Pub. Date: Nov. 4, 2010

(54) EVALUATION METHOD FOR ION BEHAVIOR AND EVALUATION DEVICE FOR ION BEHAVIOR

(75) Inventors: Masanobu Mizusaki, Osaka-shi (JP); Tatsuo Uchida, Sendai-shi (JP)

Correspondence Address: BIRCH STEWART KOLASCH & BIRCH, PO BOX 747, FALLS CHURCH, VA, 22040-0747, US

(73) Assignees: SHARP KABUSHIKI KAISHA, Osaka-shi, Osaka (JP); TOHOKU UNIVERSITY, Sendai-shi, Miyagi (JP)

(21) Appl. No.: 12/740,304

(22) PCT Filed: Aug. 26, 2008
(86) PCT No.: PCT/JP2008/065214

§ 371 Date: Jul. 23, 2010

(30) Foreign Application Priority Data
Nov. 2, 2007 (JP) 2007-286673

(51) Int. Cl. G01N 27/62; G01R 31/02

(52) U.S. Cl. 324/459; 324/760.01

(57) ABSTRACT

An evaluation device of ion behavior includes: a voltage oscillator (17) for applying, to a liquid crystal cell, a voltage including a direct-current voltage component and a voltage including no direct-current voltage component; a residual DC voltage measuring section (20) for measuring, per predetermined temperature, a plurality of combinations of (a) an application time during which the voltage including a direct-current voltage component is applied and (b) a residual DC voltage occurring after the application of the voltage; a rate measuring section (21) for measuring, per temperature, an adsorption rate coefficient of ions to an interface between a liquid crystal and an alignment film, and a desorption rate coefficient of ions from the interface, by performing curve fitting according to [Math. 1]; and an energy measuring section (22) for measuring an adsorption energy of the ions to the interface and a desorption energy of the ions from the interface, respectively, by performing curve fitting according to [Math. 2] and [Math. 3]. The evaluation device contributes to find a liquid crystal material, an alignment film material, and a combination of them, each preventing screen burn-in in a wide temperature range.

### TECHNICAL FIELD

The present invention relates to an evaluation method and an evaluation device each for evaluating behavior of ions that are included, as impurities, in a liquid crystal display element.

### BACKGROUND ART

Liquid crystal display devices are reduced in thickness and weight. Further, their power consumption is low. For these reasons, the liquid crystal display devices have been widely used as display equipment for a television, a personal computer, and a PDA in these days. In view of this, a liquid crystal display device that has high response speed in a wide range of temperature and high reliability is further expected in future.

In order to develop such a highly-reliable liquid crystal display device, liquid crystal materials and alignment film materials are also designed and developed. However, since a synthesis method of these materials varies, various impurities may be mixed in the liquid crystal material or the alignment film material at a synthesis step.

Especially, in a case where ionic impurities (impurity ions) are mixed in a liquid crystal layer provided in a liquid crystal display device, a direct-current voltage component may occur within the liquid crystal layer. The direct-current voltage component that occurs due to the presence of the impurity ions is referred to as residual DC voltage.

The reason why the residual DC voltage occurs due to the presence of the impurity ions is, more specifically, as follows. Almost all liquid crystal display devices that are currently manufactured are liquid crystal display devices employing an active matrix drive method with the use of a thin film transistor (TFT). The liquid crystal display device in this drive method is driven by a rectangular wave voltage. However, a direct-current offset voltage is superimposed on the rectangular wave voltage because parasitic capacitance of the TFT itself occurs. If impurity ions 55 (also referred to as free ions) are present in the liquid crystal layer as illustrated in (a) of FIG. 12, the impurity ions 55 are affected by the direct-current offset voltage component (direct electric field) and drift to an interface between a liquid crystal 53 and an alignment film 52, as illustrated in (b) of FIG. 12. That is, a current offset voltage component from a voltage source 56 causes the impurity ions 55 to be unevenly distributed. The impurity ions 55 thus drifting causes a residual DC voltage (an electric field shown by an arrow A), as illustrated in (b) of FIG. 12.

Since the presence of the residual DC voltage is deeply involved in an occurrence of screen burn-in or residual image, it is very important to reduce the residual DC voltage. In view of this, there have been developed liquid crystal materials and alignment film materials that reduce a residual DC voltage to be caused (Patent Literatures 1 and 2). Further, how much residual DC voltage is caused depends on not only respective properties of the liquid crystal material and the alignment film material, but also a combination of these materials. From the viewpoint of the occurrence of the residual DC voltage and the behavior of ions present in a liquid crystal layer, parameters related to the occurrence of the residual DC voltage have been clarified (Non Patent Literatures 3 and 4). That is, it is clarified that the occurrence of the residual DC voltage is determined by (i) adsorption of ions present in a liquid crystal layer on an interface between a liquid crystal and an alignment film and (ii) desorption (or dispersion) of ions from the interface.

### CITATION LIST

### Patent Literature 1

Japanese Patent Application Publication, Tokukaihei, No. 10-306281 (Publication Date: Nov. 17, 1998)

### Patent Literature 2

Japanese Patent Application Publication, Tokukaihei, No. 10-338880 (Publication Date: Dec. 22, 1998)

### Non Patent Literature 3

SID06 Digest, P-227L, pp 673-676, 2006

### Non Patent Literature 4

2006 Japanese Liquid Crystal Society annual meeting, No. 1C01, pp 63-64, 2006

### SUMMARY OF INVENTION

However, evaluation on ion behavior to reduce, in a wide temperature range, the occurrence of screen burn-in caused due to the occurrence of the residual DC voltage has not performed so far. Especially, there have not been developed techniques of reducing the residual DC voltage by optimizing a combination of a liquid crystal material and an alignment film material in accordance with evaluations on ion behavior depending on temperatures.

That is, the currently proceeding development of liquid crystal display devices are just based on evaluation on how much residual DC voltage or screen burn-in occurs in a liquid crystal display device. Namely, in the present circumstances, the development of liquid crystal display devices have not been proceeding based on evaluation on ion behavior, which is carried out in a wide temperature range. In a case where the temperature is not taken account of as above, various problems may arise as follows.

FIG. 13 shows (i) an actual measurement result of respective residual DC voltages of two types of liquid crystal display devices (Sample 1 and Sample 2) manufactured in different combinations of a liquid crystal material and an alignment film material, and (ii) respective temperature dependencies of the respective residual DC voltages of the two types of liquid crystal display devices. In FIG. 13, the residual DC voltage at 70° C. is lower in Sample 2 than in Sample 1. This demonstrates that Sample 2 exhibits a better characteristic than Sample 1 at 70° C. However, the residual DC voltage is changed depending on temperatures, and the residual DC voltage at around 25° C. is higher in Sample 2 than in Sample 1. This demonstrates that Sample 2 exhibits a poorer characteristic than Sample 1 at around 25° C. From these results, it is demonstrated that Sample 2 is poorer in characteristic than Sample 1 at practical temperatures, and the occurrence of screen burn-in is more remarkable in the combination, of Sample 2, of the liquid crystal material and the alignment film material. That is, the residual DC voltage is changed depending on temperatures even in a single sample, and the residual DC voltage is different between different samples even at the same temperature. For this reason, it is very important to evaluate the ion behavior in consideration of the temperature as a parameter, in terms of manufacturing of a liquid crystal display device that reduces the occurrence of screen burn-in.

The present invention is accomplished in view of the above problem. An object of the present invention is to provide an evaluation method for evaluating ion behavior and an evaluation device for evaluating ion behavior, each of which makes it possible to obtain a liquid crystal material, an alignment film material, and a combination of these materials, each of which prevents screen burn-in in a wide temperature range.

In order to achieve the above object, an evaluation method of the present invention for evaluating ion behavior is an evaluation method for evaluating ion behavior based on a residual DC voltage occurring in a liquid crystal cell including alignment films and a liquid crystal sandwiched therebetween, and the evaluation method of the present invention includes the steps of: (a) applying, to the liquid crystal cell, a voltage including a direct-current voltage component, followed by applying thereto a voltage including no direct-current voltage component, so as to measure, at each of a predetermined plurality of temperatures, a plurality of combinations of (i) an application time during which the voltage including a direct-current voltage component is applied to the liquid crystal cell and (ii) a residual DC voltage occurring after the application of the voltage including a direct-current voltage component to the liquid crystal cell; (b) measuring (estimating), for the each of the predetermined plurality of temperatures, an adsorption rate coefficient of ions that adsorb to an interface between the liquid crystal and one of the alignment films and a desorption rate coefficient of ions that desorb from the interface; and (c) measuring (estimating) an adsorption energy and a desorption energy by use of measurement (estimation) results of the step (b).

With the arrangement, it is possible to find, per temperature, parameters (the adsorption rate coefficient and the desorption rate coefficient) unique to a liquid crystal material and an alignment film material. These unique parameters are estimated in an adsorption process and a desorption process. Furthermore, with the above arrangement, it is possible to find an adsorption energy and a desorption energy which are unique to the liquid crystal material and the alignment film material.

As a result, it is possible to design a liquid crystal display device by selecting a liquid crystal material and an alignment film material each of which reduces the adsorption energy and the desorption energy (that is, it is possible to design a liquid crystal display device by selecting a liquid crystal material and an alignment film material each having an adsorption rate coefficient and a desorption rate coefficient which do not change so much in a wide temperature range). By designing such a liquid crystal display device, it is possible to prevent an occurrence of screen burn-in in a wide temperature range.

When the residual DC voltage occurs, ions adsorb to one of the alignment films that sandwich the liquid crystal between them while ions adsorbed on the one of the alignment films (an identical alignment film) desorb therefrom. That is, the adsorption process and the desorption process occur at the same time.

In order to achieve the above object, an evaluation method of the present invention for evaluating ion behavior is an evaluation method for evaluating ion behavior based on a residual DC voltage occurring in a liquid crystal cell including alignment films and a liquid crystal sandwiched therebetween, and the evaluation method of the present invention includes the steps of: (a) causing the liquid crystal cell to be open-circuit after applying, to the liquid crystal cell, a voltage including a direct-current voltage component, so as to measure, at each of a predetermined plurality of temperatures, a plurality of combinations of an open-circuit time and a residual DC voltage occurring after the liquid crystal cell is caused to be open-circuit; (b) measuring (estimating), for the each of the predetermined plurality of temperatures, a first relaxation rate coefficient and a second relaxation rate coefficient from among a plurality of relaxation rate coefficients of ions relaxed from an interface between the liquid crystal and one of the alignment films; and (c) measuring (estimating) a first relaxation energy and a second relaxation energy with the use of measurement (estimation) results of the step (b).

With the above arrangement, it is possible to find, per temperature, parameters (two relaxation rate coefficients) unique to a liquid crystal material and an alignment film material. Further, with the above arrangement, it is possible to find two relaxation energies unique to the liquid crystal material and the alignment film material.

As a result, it is possible to design a liquid crystal display device by selecting a liquid crystal material and an alignment film material each of which more reduces the relaxation energies (that is, it is possible to design a liquid crystal display device by selecting a liquid crystal material and an alignment film material each having an adsorption rate coefficient and a desorption rate coefficient which do not change so much in a wide temperature range). By designing such a liquid crystal display device, it is possible to prevent an occurrence of screen burn-in in a wide temperature range.

A reason why there are at least two types of relaxation rates and relaxation energies is because in the liquid crystal cell, there are a plurality of sites (alignment films) to which ions adsorb and there are a plurality of ions (impurity ions).

In order to achieve the above object, an evaluation method of the present invention for evaluating ion behavior is an evaluation method for evaluating ion behavior based on a residual DC voltage occurring in a liquid crystal cell including alignment films and a liquid crystal sandwiched therebetween, and the evaluation method of the present invention includes the steps of: applying, to the liquid crystal cell, a voltage including a direct-current voltage component, followed by applying thereto a voltage including no direct-current voltage component, so as to measure, at each of a predetermined plurality of temperatures, a plurality of combinations of (i) an application time during which the voltage including a direct-current voltage component is applied to the liquid crystal cell and (ii) a residual DC voltage occurring after the application of the voltage including a direct-current voltage component to the liquid crystal cell; and measuring (estimating) (a) an adsorption rate coefficient of ions that adsorb to an interface between the liquid crystal and one of the alignment films and (b) a desorption rate coefficient of ions that desorb from the interface, by performing curve fitting according to the following equation:

$${V}_{rDC} ( t ) = ( \frac{q}{{C}_{LC}} ) ( \frac{{k}_{a} {n}_{f}}{{k}_{a} {n}_{f} + {k}_{d}} ) N [ 1 - exp \{ - ( {k}_{a} {n}_{f} + {k}_{d} ) t \} ] \qquad [ Math . 1 ]$$

the adsorption rate coefficient and the desorption rate coefficient being measured (estimated) for the each of the predetermined plurality of temperatures; and measuring (estimating) (c) an adsorption energy of the ions that adsorb to the interface, by performing curve fitting according to the following equation:

$${k}_{a} {n}_{f} = {( {k}_{a} {n}_{f} )}_{0} exp ( - \frac{{E}_{a}}{kT} ) \qquad [ Math . 2 ]$$

and (d) a desorption energy of the ions that desorb from the interface, by performing curve fitting according to the following equation:

$${k}_{d} = {( {k}_{d} )}_{0} exp ( - \frac{{E}_{d}}{kT} ) \qquad [ Math . 3 ]$$

(where, in each of the equations, V_{rDC} is a residual DC voltage; t is an application time during which the voltage including a direct-current voltage component is applied; kₐ is a rate coefficient of ions, in a liquid crystal layer, that adsorb to the interface; kd is a desorption rate coefficient of desorbing, from the interface, ions that are adsorbed on the interface; n_{f} is an ion density in the liquid crystal layer; q is elementary charge; C_{LC} is capacitance of the liquid crystal layer; k is a Boltzmann constant; T is an absolute temperature; Eₐ is an adsorption energy of the ions that adsorb to the interface; kₐ·n_{f} is an adsorption rate coefficient of the ions that adsorb to the interface; and Ed is a desorption energy of the ions that desorb from the interface).

Here, “ions” in the ion behavior indicates impurity ions that are mixed into a liquid crystal layer in the course of manufacturing a liquid crystal cell.

In the above arrangement, curve fitting is performed twice. By the first curve fitting according to [Math. 1], the adsorption rate coefficient and the desorption rate coefficient are found. Then, by the second curve fitting according to [Math. 2] and [Math. 3], the adsorption energy and the desorption energy are found, respectively.

Further, by performing the curve fitting according to [Math. 1] on the basis of the plurality of combinations of the application time during which the voltage including a direct-current voltage component is applied and the residual DC voltage, it is possible to obtain the adsorption rate coefficient and the desorption rate coefficient, which are parameters of [Math. 1].

Similarly, by performing the curve fitting according to [Math. 2] on the basis of the combination of a temperature and an adsorption rate, it is possible to measure (estimate) the adsorption energy of ions that adsorb to the interface. The adsorption energy is a parameter of [Math. 2].

Furthermore, by performing the curve fitting according to [Math. 3] on the basis of the combination of a temperature and the desorption rate coefficient, it is possible to measure (estimate) the desorption energy of ions that desorb from the interface. The desorption energy is a parameter of [Math. 3].

Accordingly, with the above arrangement, it is possible to find, per temperature, parameters (the adsorption rate coefficient and the desorption rate coefficient) unique to a liquid crystal material and an alignment film material. These parameters are estimated in an adsorption process and a desorption process. Further, with the above arrangement, it is possible to find an adsorption energy and a desorption energy unique to the liquid crystal material and the alignment film material.

As a result, it is possible to design a liquid crystal display device by selecting a liquid crystal material and an alignment film material each of which reduces the adsorption energy and the desorption energy (that is, it is possible to design a liquid crystal display device by selecting a liquid crystal material and an alignment film material each having an adsorption rate coefficient and a desorption rate coefficient which do not change so much in a wide temperature range). By designing such a liquid crystal display device, it is possible to prevent an occurrence of screen burn-in in a wide temperature range.

When the residual DC voltage occurs, ions adsorb to one of the alignment films that sandwich the liquid crystal between them while ions that are adsorbed on the one of the alignment films (an identical alignment film) desorb therefrom. That is, the adsorption process and the desorption process occur at the same time.

In order to achieve the above object, an evaluation method of the present invention for evaluating ion behavior is an evaluation method for evaluating ion behavior based on a residual DC voltage occurring in a liquid crystal cell including alignment films and a liquid crystal sandwiched therebetween, and the evaluation method of the present invention includes the steps of: causing the liquid crystal cell to be open-circuit after applying, to the liquid crystal cell, a voltage including a direct-current voltage component, so as to measure, at each of a predetermined plurality of temperatures, a plurality of combinations of an open-circuit time and a residual DC voltage occurring after the liquid crystal cell is caused to be open-circuit; measuring (estimating) a first relaxation rate coefficient and a second relaxation rate coefficient from among a plurality of relaxation rate coefficients of ions relaxed from an interface between the liquid crystal and one of the alignment films, by performing curve fitting according to the following equation:

$${V}_{rDC} ( t ) = ( \frac{q}{{C}_{LC}} ) {n}_{a} ( 0 ) [ \begin{matrix}A exp ( - \frac{t}{{τ}_{R 1}} ) + \\ ( 1 - A ) exp ( - \frac{t}{{τ}_{R 2}} )\end{matrix} ] \qquad [ Math . 4 ]$$

the first relaxation rate coefficient and the second relaxation rate coefficient being measured (estimated) for the each of the predetermined plurality of temperatures; and measuring (estimating) (a) a first relaxation energy of ions relaxed from the interface, by performing curve fitting according to the following equation:

$$\frac{1}{{τ}_{R 1}} = {( \frac{1}{{τ}_{R 1}} )}_{0} exp ( - \frac{{E}_{R 1}}{kT} ) \qquad [ Math . 5 ]$$

and (b) a second relaxation energy of ions relaxed from the interface, by performing curve fitting according to the following equation:

$$\frac{1}{{τ}_{R 2}} = {( \frac{1}{{τ}_{R 2}} )}_{0} exp ( - \frac{{E}_{R 2}}{kT} ) \qquad [ Math . 6 ]$$

(where, in each of the equations, V_{rDC} is a residual DC voltage; t is an open-circuit time; q is elementary charge; C_{LC} is capacitance of a liquid crystal layer; 1/τ_{R1} is the first relaxation rate coefficient; 1/τ_{R2} is the second relaxation rate coefficient; k is a Boltzmann constant; E_{R1} is the first relaxation energy; nₐ(0) is a density of ions that are adsorbed on the interface right after the relaxation; A is a ratio of ions having the first relaxation rate coefficient; 1−A is a ratio of ions having the second relaxation rate coefficient; T is an absolute temperature; and E_{R2} is the second relaxation energy).

Here, “ions” in the ion behavior indicates impurity ions that are mixed into a liquid crystal layer in the course of manufacturing a liquid crystal cell.

In the above arrangement, curve fitting is performed twice. By the first curve fitting according to [Math. 4], the first relaxation coefficient and the second relaxation coefficient are found per temperature from among a plurality of relaxation rate coefficients of ions relaxed from the interface between the liquid crystal and one of the alignment films. Then, by the second curve fitting according to [Math. 11] and [Math. 12], the first relaxation energy and the second relaxation energy are found, respectively.

Further, after the voltage including a direct-current voltage component is applied to the liquid crystal cell, the liquid crystal cell is caused to be open-circuit. Then, by performing, at each of a plurality of temperatures, the curve fitting according to [Math. 4] on the basis of the combinations of the open-circuit time and the residual DC voltage occurring after the liquid crystal cell is caused to be open-circuit, it is possible to obtain the first relaxation rate coefficient and the second relaxation rate coefficient, which are parameters of [Math. 4].

Similarly, by performing the curve fitting according to [Math. 5] on the basis of the combination of a temperature and the first relaxation rate coefficient, it is possible to measure (estimate) the first relaxation energy of ions relaxed from the interface. The first relaxation energy is a parameter of [Math. 5].

Furthermore, by performing the curve fitting according to [Math. 6] on the basis of the combination of a temperature and the second relaxation rate coefficient, it is possible to measure (estimate) the second relaxation energy of ions relaxed from the interface. The second relaxation energy is a parameter of [Math. 6].

Accordingly, with the above arrangement, it is possible to find, per temperature, parameters (two relaxation rate coefficients) unique to a liquid crystal material and an alignment film material. These parameters are estimated in an adsorption process and a desorption process. Further, with the above arrangement, it is possible to find two relaxation energies unique to the liquid crystal material and the alignment material.

As a result, it is possible to design a liquid crystal display device by selecting a liquid crystal material and an alignment film material each of which reduces the relaxation energies (that is, it is possible to design a liquid crystal display device by selecting a liquid crystal material and an alignment film material each having an adsorption rate coefficient and a desorption rate coefficient which do not change so much in a wide temperature range). By designing such a liquid crystal display device, it is possible to prevent an occurrence of screen burn-in in a wide temperature range.

A reason why there are at least two types of relaxation rates and relaxation energies is because in the liquid crystal cell, there are a plurality of sites (alignment films) to which ions adsorb and there are a plurality of ions (impurity ions).

Further, in the evaluation method of the present invention for evaluating ion behavior, it is preferable that the residual DC voltage be measured by a flicker elimination method.

Further, in the evaluation method of the present invention for evaluating ion behavior, it is preferable that the curve fittings be performed by a least-square method so that a standard deviation takes a minimum value.

Moreover, in order to achieve the above object, an evaluation device of the present invention for evaluating ion behavior is an evaluation device for evaluating ion behavior based on a residual DC voltage occurring in a liquid crystal cell including alignment films and a liquid crystal sandwiched therebetween, and the evaluation device of the present invention includes: a voltage application section for applying, to the liquid crystal cell, a voltage including a direct-current voltage component and a voltage including no direct-current voltage component; a residual DC voltage measuring section for measuring, at each of a predetermined plurality of temperatures, a plurality of combinations of (i) an application time during which the voltage including a direct-current voltage component is applied to the liquid crystal cell and (ii) a residual DC voltage occurring after the application of the voltage including a direct-current voltage component to the liquid crystal cell; a rate measuring section (rate estimating section) for measuring (estimating) (a) an adsorption rate coefficient of ions that adsorb to an interface between the liquid crystal and one of the alignment films and (b) a desorption rate coefficient of ions that desorb from the interface, by performing curve fitting according to the following equation:

$${V}_{rDC} ( t ) = ( \frac{q}{{C}_{LC}} ) ( \frac{{k}_{a} {n}_{f}}{{k}_{a} {n}_{f} + {k}_{d}} ) N [ 1 - exp \{ - ( {k}_{a} {n}_{f} + {k}_{d} ) t \} ] \qquad [ Math . 7 ]$$

the rate measuring section (the rate estimating section) measuring (estimating) the adsorption rate coefficient and the desorption rate coefficient for the each of the predetermined plurality of temperatures; and an energy measuring section (energy estimating section) for measuring (estimating) (c) an adsorption energy of the ions that adsorb to the interface, by performing curve fitting according to the following equation:

$${k}_{a} {n}_{f} = {( {k}_{a} {n}_{f} )}_{0} exp ( - \frac{{E}_{a}}{kT} ) \qquad [ Math . 8 ]$$

and (d) a desorption energy of the ions that desorb from the interface, by performing curve fitting according to the following equation:

$${k}_{d} = {( {k}_{d} )}_{0} exp ( - \frac{{E}_{d}}{kT} ) \qquad [ Math . 9 ]$$

(where, in each of the equations, V_{rDC} is a residual DC voltage; t is an application time during which the voltage including a direct-current voltage component is applied; kₐ is a rate coefficient of ions, in a liquid crystal layer, that adsorb to the interface; kd is a desorption rate coefficient of desorbing, from the interface, ions that are adsorbed on the interface; N is a density of ions adsorbed on the interface; n_{f} is an ion density in the liquid crystal layer; q is elementary charge; C_{LC} is capacitance of the liquid crystal layer; k is a Boltzmann constant; T is an absolute temperature; Eₐ is an adsorption energy of the ions that adsorb to the interface; kₐ·n_{f} is an adsorption rate coefficient of the ions that adsorb to the interface; and Ed is a desorption energy of the ions that desorb from the interface).

Here, “ions” in the ion behavior indicates impurity ions that are mixed into a liquid crystal layer in the course of manufacturing a liquid crystal cell.

In the above arrangement, curve fitting is performed twice. By the first curve fitting according to [Math. 7], the adsorption rate coefficient and the desorption rate coefficient are found. Then, by the second curve fitting according to [Math. 8] and [Math. 9], the adsorption energy and the desorption energy are found, respectively.

Further, by performing the curve fitting according to [Math. 7] on the basis of the plurality of combinations of the application time during which the voltage including a direct-current voltage component is applied and the residual DC voltage, it is possible to obtain the adsorption rate coefficient and the desorption rate coefficient, which are parameters of [Math. 7].

Similarly, by performing the curve fitting according to [Math. 8] on the basis of the combination of a temperature and the adsorption rate coefficient, it is possible to measure (estimate) the adsorption energy of ions that adsorb to the interface. The adsorption energy is a parameter of [Math. 8].

Furthermore, by performing the curve fitting according to [Math. 9] on the basis of the combination of a temperature and the desorption rate coefficient, it is possible to measure (estimate) the desorption energy of ions that desorb from the interface. The desorption energy is a parameter of [Math. 9].

Accordingly, with the above arrangement, it is possible to find, per temperature, parameters (the adsorption rate coefficient and the desorption rate coefficient) unique to a liquid crystal material and an alignment film material. These parameters are estimated in an adsorption process and a desorption process. Further, with the above arrangement, it is possible to find an adsorption energy and a desorption energy unique to the liquid crystal material and the alignment material.

As a result, it is possible to design a liquid crystal display device by selecting a liquid crystal material and an alignment film material each of which reduces the adsorption energy and the desorption energy (that is, it is possible to design a liquid crystal display device by selecting a liquid crystal material and an alignment film material each having an adsorption rate coefficient and a desorption rate coefficient which do not change so much in a wide temperature range). By designing such a liquid crystal display device, it is possible to prevent an occurrence of screen burn-in in a wide temperature range.

When the residual DC voltage occurs, ions adsorb to one of the alignment films that sandwich the liquid crystal between them while ions that are adsorbed on the one of the alignment films (an identical alignment film) desorb therefrom. That is, the adsorption process and the desorption process occur at the same time.

In order to achieve the above object, an evaluation device of the present invention for evaluating ion behavior is an evaluation device for evaluating ion behavior based on a residual DC voltage occurring in a liquid crystal cell including alignment films and a liquid crystal sandwiched therebetween, and the evaluation device of the present invention includes: a voltage application section for applying, to the liquid crystal cell, a voltage including a direct-current voltage component; a residual DC voltage measuring section for measuring, at each of a predetermined plurality of temperatures, a plurality of combinations of (i) an open-circuit time during which the liquid crystal cell, to which the voltage including a direct-current voltage component has been applied, is being open-circuit and (ii) a residual voltage occurring after the liquid crystal cell is caused to be open-circuit; a rate measuring section (rate estimating section) for measuring (estimating) a first relaxation rate coefficient and a second relaxation rate coefficient from among a plurality of relaxation rate coefficients of ions relaxed from an interface between the liquid crystal and one of the alignment films, by performing curve fitting according to the following equation:

$${V}_{rDC} ( t ) = ( \frac{q}{{C}_{LC}} ) {n}_{a} ( 0 ) [ \begin{matrix}A exp ( - \frac{t}{{τ}_{R 1}} ) + \\ ( 1 - A ) exp ( - \frac{t}{{τ}_{R 2}} )\end{matrix} ] \qquad [ Math . 10 ]$$

the rate measuring section (the rate estimating section) measuring (estimating) the first relaxation rate coefficient and the second relaxation rate coefficient for the each of the predetermined plurality of temperatures; and an energy measuring section (energy estimating section) for measuring (estimating) (a) a first relaxation energy of ions relaxed from the interface, by performing curve fitting according to the following equation:

$$\frac{1}{{τ}_{R 1}} = {( \frac{1}{{τ}_{R 1}} )}_{0} exp ( - \frac{{E}_{R 1}}{kT} ) \qquad [ Math . 11 ]$$

and (b) a second relaxation energy of ions relaxed from the interface, by performing curve fitting according to the following equation:

$$\frac{1}{{τ}_{R 2}} = {( \frac{1}{{τ}_{R 2}} )}_{0} exp ( - \frac{{E}_{R 2}}{kT} ) \qquad [ Math . 12 ]$$

(where, in each of the equations, V_{rDC} is a residual DC voltage; t is an open-circuit time; q is elementary charge; C_{LC} is capacitance of the liquid crystal layer; 1/τ_{R1} is the first relaxation rate coefficient; 1/τ_{R2} is the second relaxation rate coefficient; k is a Boltzmann constant; E_{R1} is the first relaxation energy; nₐ(0) is a density of ions that are adsorbed on the interface right after the relaxation; A is a ratio of ions having the first relaxation rate coefficient; 1−A is a ratio of ions having the second relaxation rate coefficient; T is an absolute temperature; and E_{R2} is the second relaxation energy.)

Here, “ions” in the ion behavior indicates impurity ions that are mixed into a liquid crystal layer in the course of manufacturing a liquid crystal cell.

In the above arrangement, curve fitting is performed twice. By the first curve fitting according to [Math. 10], the first relaxation coefficient and the second relaxation coefficient are found per temperature from among a plurality of relaxation rate coefficients of ions relaxed from the interface between the liquid crystal and one of the alignment films. Then, by the second curve fitting according to [Math. 5] and [Math. 6], the first relaxation energy and the second relaxation energy are found, respectively.

Further, after the voltage including a direct-current voltage component is applied to the liquid crystal cell, the liquid crystal cell is caused to be open-circuit. Then, by performing, at each of a plurality of temperatures, the curve fitting according to [Math. 10] on the basis of the combinations of the open-circuit time and the residual DC voltage occurring after the liquid crystal cell is caused to be open-circuit, it is possible to obtain the first relaxation rate coefficient and the second relaxation rate coefficient, which are parameters of [Math. 10].

Similarly, by performing the curve fitting according to [Math. 11] on the basis of the combination of a temperature and the first relaxation rate coefficient, it is possible to measure (estimate) the first relaxation energy of ions relaxed from the interface. The first relaxation energy is a parameter of [Math. 11].

Furthermore, by performing the curve fitting according to [Math. 12] on the basis of the combination of a temperature and the second relaxation rate coefficient, it is possible to measure (estimate) the second relaxation energy of ions relaxed from the interface. The second relaxation energy is a parameter of [Math. 12].

Accordingly, with the above arrangement, it is possible to find, per temperature, parameters (two relaxation rate coefficient) unique to a liquid crystal material and an alignment film material. Further, with the above arrangement, it is possible to find two relaxation energies unique to the liquid crystal material and the alignment material.

As a result, it is possible to design a liquid crystal display device by selecting a liquid crystal material and an alignment film material each of which reduces the relaxation energies (that is, it is possible to design a liquid crystal display device by selecting a liquid crystal material and an alignment film material each having an adsorption rate coefficient and a desorption rate coefficient which do not change so much in a wide temperature range). By designing such a liquid crystal display device, it is possible to prevent an occurrence of screen burn-in in a wide temperature range.

A reason why there are at least two types of relaxation rates and relaxation energies is because in the liquid crystal cell, there are a plurality of sites (alignment films) to which ions adsorb and there are a plurality of ions (impurity ions).

Further, in the evaluation device of the present invention for evaluating ion behavior, it is preferable that the residual DC voltage be measured by a flicker elimination method.

Further, in the evaluation device of the present invention for evaluating ion behavior, it is preferable that the curve fittings be performed by a least-square method so that a standard deviation takes a minimum value.

As described above, an evaluation method of the present invention for evaluating ion behavior is an evaluation method for evaluating ion behavior based on a residual DC voltage occurring in a liquid crystal cell including alignment films and a liquid crystal sandwiched therebetween, and the evaluation method of the present invention includes the steps of: (a) applying, to the liquid crystal cell, a voltage including a direct-current voltage component, followed by applying thereto a voltage including no direct-current voltage component, so as to measure, at each of a predetermined plurality of temperatures, a plurality of combinations of (i) an application time during which the voltage including a direct-current voltage component is applied to the liquid crystal cell and (ii) a residual DC voltage occurring after the application of the voltage including a direct-current voltage component to the liquid crystal cell; (b) measuring (estimating), for the each of the predetermined plurality of temperatures, an adsorption rate coefficient of ions that adsorb to an interface between the liquid crystal and one of the alignment films and a desorption rate coefficient of ions that desorb from the interface; and (c) measuring (estimating) an adsorption energy and a desorption energy by use of measurement (estimation) results of the step (b).

Further, an evaluation method of the present invention for evaluating ion behavior is an evaluation method for evaluating ion behavior based on a residual DC voltage occurring in a liquid crystal cell including alignment films and a liquid crystal sandwiched therebetween, and the evaluation method of the present invention includes the steps of: (a) causing the liquid crystal cell to be open-circuit after applying, to the liquid crystal cell, a voltage including a direct-current voltage component, so as to measure, at each of a predetermined plurality of temperatures, a plurality of combinations of an open-circuit time and a residual DC voltage occurring after the liquid crystal cell is caused to be open-circuit; (b) measuring (estimating), for the each of the predetermined plurality of temperatures, a first relaxation rate coefficient and a second relaxation rate coefficient from among a plurality of relaxation rate coefficients of ions relaxed from an interface between the liquid crystal and one of the alignment films; and (c) measuring (estimating) a first relaxation energy and a second relaxation energy with the use of measurement (estimation) results of the step (b).

Further, an evaluation method of the present invention for evaluating ion behavior is an evaluation method for evaluating ion behavior based on a residual DC voltage occurring in a liquid crystal cell including alignment films and a liquid crystal sandwiched therebetween, and the evaluation method of the present invention includes the steps of: applying, to the liquid crystal cell, a voltage including a direct-current voltage component, followed by applying thereto a voltage including no direct-current voltage component, so as to measure, at each of a predetermined plurality of temperatures, a plurality of combinations of (i) an application time during which the voltage including a direct-current voltage component is applied to the liquid crystal cell and (ii) a residual DC voltage occurring after the application of the voltage including a direct-current voltage component to the liquid crystal cell; and measuring (estimating) (a) an adsorption rate coefficient of ions that adsorb to an interface between the liquid crystal and one of the alignment films and (b) a desorption rate coefficient of ions that desorb from the interface, by performing curve fitting according to the following equation:

$${V}_{rDC} ( t ) = ( \frac{q}{{C}_{LC}} ) ( \frac{{k}_{a} {n}_{f}}{{k}_{a} {n}_{f} + {k}_{d}} ) N [ 1 - exp \{ - ( {k}_{a} {n}_{f} + {k}_{d} ) t \} ] \qquad [ Math . 13 ]$$

the adsorption rate coefficient and the desorption rate coefficient being measured (estimated) for the each of the predetermined plurality of temperatures; and measuring (estimating) (c) an adsorption energy of the ions that adsorb to the interface, by performing curve fitting according to the following equation:

$${k}_{a} {n}_{f} = {( {k}_{a} {n}_{f} )}_{0} exp ( - \frac{{E}_{a}}{kT} ) \qquad [ Math . 14 ]$$

and (d) a desorption energy of the ions that desorb from the interface, by performing curve fitting according to the following equation:

$${k}_{d} = {( {k}_{d} )}_{0} exp ( - \frac{{E}_{d}}{kT} ) \qquad [ Math . 15 ]$$

(where, in each of the equations, V_{rDC} is a residual DC voltage; t is an application time during which the voltage including a direct-current voltage component is applied; kₐ is a rate coefficient of ions, in a liquid crystal layer, that adsorb to the interface; kd is a desorption rate coefficient of desorbing, from the interface, ions that are adsorbed on the interface; n_{f} is an ion density in the liquid crystal layer; q is elementary charge; C_{LC} is capacitance of the liquid crystal layer; k is a Boltzmann constant; T is an absolute temperature; Eₐ is an adsorption energy of the ions that adsorb to the interface; kₐ·n_{f} is an adsorption rate coefficient of the ions that adsorb to the interface; and Ed is a desorption energy of the ions that desorb from the interface).

Further, an evaluation method of the present invention for evaluating ion behavior is an evaluation method for evaluating ion behavior based on a residual DC voltage occurring in a liquid crystal cell including alignment films and a liquid crystal sandwiched therebetween, and the evaluation method of the present invention includes the steps of: causing the liquid crystal cell to be open-circuit after applying, to the liquid crystal cell, a voltage including a direct-current voltage component, so as to measure, at each of a predetermined plurality of temperatures, a plurality of combinations of an open-circuit time and a residual DC voltage occurring after the liquid crystal cell is caused to be open-circuit; measuring (estimating) a first relaxation rate and a second relaxation rate of ions relaxed from an interface between the liquid crystal and one of the alignment films, by performing curve fitting according to the following equation:

$${V}_{rDC} ( t ) = ( \frac{q}{{C}_{LC}} ) {n}_{a} ( 0 ) [ A exp ( - \frac{t}{{τ}_{R 1}} ) + ( 1 - A ) exp ( - \frac{t}{{τ}_{R 2}} ) ] \qquad [ Math . 16 ]$$

the first relaxation rate and the second relaxation rate being measured (estimated) for the each of the predetermined plurality of temperatures; measuring (estimating) (a) a first relaxation energy of ions relaxed from the interface, by performing curve fitting according to the following equation:

$$\frac{1}{{τ}_{R 1}} = {( \frac{1}{{τ}_{R 1}} )}_{0} exp ( - \frac{{E}_{R 1}}{kT} ) \qquad [ Math . 17 ]$$

and (b) a second relaxation energy of ions relaxed from the interface, by performing curve fitting according to the following equation:

$$\frac{1}{{τ}_{R 2}} = {( \frac{1}{{τ}_{R 2}} )}_{0} exp ( - \frac{{E}_{R 2}}{kT} ) \qquad [ Math . 18 ]$$

(where, in each of the equations, V_{rDC} is a residual DC voltage; t is an open-circuit time; q is elementary charge; C_{LC} is capacitance of the liquid crystal layer; 1/τ_{R1} is the first relaxation rate; 1/τ_{R2} is the second relaxation rate; k is a Boltzmann constant; E_{R1} is the first relaxation energy; nₐ(0) is a density of ions that are adsorbed on the interface right after the relaxation; A is a ratio of ions having the first relaxation rate; 1−A is a ratio of ions having the second relaxation rate; T is an absolute temperature; and E_{R2} is the second relaxation energy).

Further, an evaluation device of the present invention for evaluating ion behavior is an evaluation device for evaluating ion behavior based on a residual DC voltage occurring in a liquid crystal cell including alignment films and a liquid crystal sandwiched therebetween, and the evaluation device of the present invention includes: a voltage application section for applying, to the liquid crystal cell, a voltage including a direct-current voltage component and a voltage including no direct-current voltage component; a residual DC voltage measuring section for measuring, at each of a predetermined plurality of temperatures, a plurality of combinations of (i) an application time during which the voltage including a direct-current voltage component is applied to the liquid crystal cell and (ii) a residual DC voltage occurring after the application of the voltage including a direct-current voltage component to the liquid crystal cell; a rate measuring section (rate estimating section) for measuring (estimating) (a) an adsorption rate coefficient of ions that adsorb to an interface between the liquid crystal and one of the alignment films and (b) a desorption rate coefficient of ions that desorb from the interface, by performing curve fitting according to the following equation:

$${V}_{rDC} ( t ) = ( \frac{q}{{C}_{LC}} ) ( \frac{{k}_{a} {n}_{f}}{{k}_{a} {n}_{f} + {k}_{d}} ) N [ 1 - exp \{ - ( {k}_{a} {n}_{f} + {k}_{d} ) t \} ] \qquad [ Math . 19 ]$$

the rate measuring section (the rate estimating section) measuring (estimating) the adsorption rate coefficient and the desorption rate coefficient for the each of the predetermined plurality of temperatures; and an energy measuring section (energy estimating section) for measuring (estimating) (c) an adsorption energy of the ions that adsorb to the interface, by performing curve fitting according to the following equation:

$${k}_{a} {n}_{f} = {( {k}_{a} {n}_{f} )}_{0} exp ( - \frac{{E}_{a}}{kT} ) \qquad [ Math . 20 ]$$

and (d) a desorption energy of the ions that desorb from the interface, by performing curve fitting according to the following equation:

$${k}_{d} = {( {k}_{d} )}_{0} exp ( - \frac{{E}_{d}}{kT} ) \qquad [ Math . 21 ]$$

(where, in each of the equations, V_{rDC} is a residual DC voltage; t is an application time during which the voltage including a direct-current voltage component is applied; kₐ is a rate coefficient of ions, in a liquid crystal layer, that adsorb to the interface; kd is a desorption rate coefficient of desorbing, from the interface, ions that are adsorbed on the interface; N is a density of ions adsorbed on the interface; n_{f} is an ion density in the liquid crystal layer; q is elementary charge; C_{LC} is capacitance of the liquid crystal layer; k is a Boltzmann constant; T is an absolute temperature; Eₐ is an adsorption energy of the ions that adsorb to the interface; kₐ·n_{f} is an adsorption rate coefficient of the ions that adsorb to the interface; and Ed is a desorption energy of the ions that desorb from the interface).

Further, an evaluation device of the present invention for evaluating ion behavior is an evaluation device for evaluating ion behavior based on a residual DC voltage occurring in a liquid crystal cell including alignment films and a liquid crystal sandwiched therebetween, and the evaluation device of the present invention includes: a voltage application section for applying, to the liquid crystal cell, a voltage including a direct-current voltage component; a residual DC voltage measuring section for measuring, at each of a predetermined plurality of temperatures, a plurality of combinations of (i) an open-circuit time during which the liquid crystal cell, to which the voltage including a direct-current voltage component has been applied, is being open-circuit and (ii) a residual voltage occurring after the liquid crystal cell is caused to be open-circuit; a rate measuring section (rate estimating section) for measuring (estimating) a first relaxation rate coefficient and a second relaxation rate coefficient from among a plurality of relaxation rate coefficients of ions relaxed from an interface between the liquid crystal and one of the alignment films, by performing curve fitting according to the following equation:

$${V}_{rDC} ( t ) = ( \frac{q}{{C}_{LC}} ) {n}_{a} ( 0 ) [ A exp ( - \frac{t}{{τ}_{R 1}} ) + ( 1 - A ) exp ( - \frac{t}{{τ}_{R 2}} ) ] \qquad [ Math . 22 ]$$

the rate measuring section (rate estimating section) measuring (estimating) the first relaxation rate coefficient and the second relaxation rate coefficient for the each of the predetermined plurality of temperatures; and an energy measuring section (energy estimating section) for measuring (estimating) (a) a first relaxation energy of ions relaxed from the interface, by performing curve fitting according to the following equation:

$$\frac{1}{{τ}_{R 1}} = {( \frac{1}{{τ}_{R 1}} )}_{0} exp ( - \frac{{E}_{R 1}}{kT} ) \qquad [ Math . 23 ]$$

and (b) a second relaxation energy of ions relaxed from the interface, by performing curve fitting according to the following equation:

$$\frac{1}{{τ}_{R 2}} = {( \frac{1}{{τ}_{R 2}} )}_{0} exp ( - \frac{{E}_{R 2}}{kT} ) \qquad [ Math . 24 ]$$

(where, in each of the equations, V_{rDC} is a residual DC voltage; t is an open-circuit time; q is elementary charge; C_{LC} is capacitance of the liquid crystal layer; 1/τ_{R1} is the first relaxation rate coefficient; 1/τ_{R2} is the second relaxation rate coefficient; k is a Boltzmann constant; E_{R1} is the first relaxation energy; nₐ(0) is a density of ions that are adsorbed on the interface right after the relaxation; A is a ratio of ions having the first relaxation rate coefficient; 1−A is a ratio of ions having the second relaxation rate coefficient; T is an absolute temperature; and E_{R2} is the second relaxation energy).

In this way, it is possible to provide an evaluation method for evaluating ion behavior and an evaluation device for evaluating ion behavior each of which makes it possible to obtain a liquid crystal material, an alignment film material, and a combination of these materials, each of which prevents an occurrence of screen burn-in in a wide temperature range.

Additional objects, features, and strengths of the present invention will be made clear by the description below. Further, the advantages of the present invention will be evident from the following explanation in reference to the drawings.

### BRIEF DESCRIPTION OF DRAWINGS

FIG. 1

FIG. 1 is a block diagram illustrating an evaluation apparatus of the present invention for evaluating ion behavior.

FIG. 2

FIG. 2 is an explanatory view of a residual DC voltage.

FIG. 3

FIG. 3 is an explanatory view of flicker.

FIG. 4

FIG. 4 is a graph showing a relationship between a residual DC voltage and an application time of a voltage including a direct-current offset.

FIG. 5

FIG. 5 is a graph showing a relationship between a residual DC voltage and an application time at a plurality of temperatures.

FIG. 6

FIG. 6 is a graph of a desorption rate coefficient and an adsorption rate coefficient obtained per temperature by performing curve fittings.

FIG. 7

FIG. 7 is a graph showing a result of an Arrhenius plot performed on the plots in the graph of FIG. 6.

FIG. 8

FIG. 8 is a graph showing a relationship between a residual DC time and an open-circuit time.

FIG. 9

FIG. 9 is a graph showing respective relationships between a residual DC time and an open-circuit time at a plurality of temperatures.

FIG. 10

FIG. 10 is a graph showing a first relaxation rate coefficient and a second relaxation rate coefficient obtained per temperature by performing curve fittings.

FIG. 11

FIG. 11 is a graph showing a result of an Arrhenius plot performed on the plots in the graph of FIG. 10.

FIG. 12

FIG. 12 is an explanatory view of a residual DC voltage.

FIG. 13

FIG. 13 is a graph showing respective relationships between a residual DC voltage and a temperature in Sample 1 and Sample 2.

### REFERENCE SIGNS LIST

1 Alignment Film
2 Alignment Film
3 Liquid Crystal (Liquid Crystal Layer)
17 Voltage Oscillator (Voltage Application Section)
20 Residual DC Voltage Measuring Section
21 Rate Measuring Section (Rate Estimating Section)
22 Energy Measuring Section (Energy Estimating Section)

### DESCRIPTION OF EMBODIMENTS

### Embodiment 1

### Residual DC Voltage

Embodiments of the present invention relate to an evaluation device and an evaluation method each for evaluating ion behavior. However, prior to explanation of the evaluation device and the evaluation method, the following describes a residual DC voltage, with reference to (a) and (b) of FIG. 2. (a) of FIG. 2 is a view schematically illustrating a liquid crystal cell 14 in a short-circuit condition (no voltage is applied), and (b) of FIG. 2 is a view schematically illustrating the liquid crystal cell 14 to which a direct-current voltage component is being applied.

As illustrated in (a) of FIG. 2, the liquid crystal cell 14 is constituted by: alignment films 1 and 2, which are provided so as to face each other; and a liquid crystal layer (liquid crystal) 3 sandwiched between the alignment films 1 and 2. Further, the alignment films 1 and 2 are connected to each other via a wiring line 4, for convenience. The wiring line 4 is provided on one surfaces of the alignment films 1 and 2 which surfaces do not face one another.

The liquid crystal layer (liquid crystal) 3 contains ionic impurities (ions) 5. The ions 5 are caused in the liquid crystal layer 3 at the time of synthesis of materials of the alignment films 1 and 2 and the liquid crystal layer 3, or alternatively, the ions 5 are mixed into the liquid crystal layer 3 in the course of a panel forming process. The ions 5 illustrated in FIG. 2 have positive charge, as an example.

The liquid crystal cell 14 is a liquid crystal cell for use in, what is called, a liquid crystal display device employing a TFT (Thin Film Transistor) drive method. Therefore, a direct-current voltage component is applied to either end of the liquid crystal cell 14 because parasitic capacitance of the TFT itself occurs.

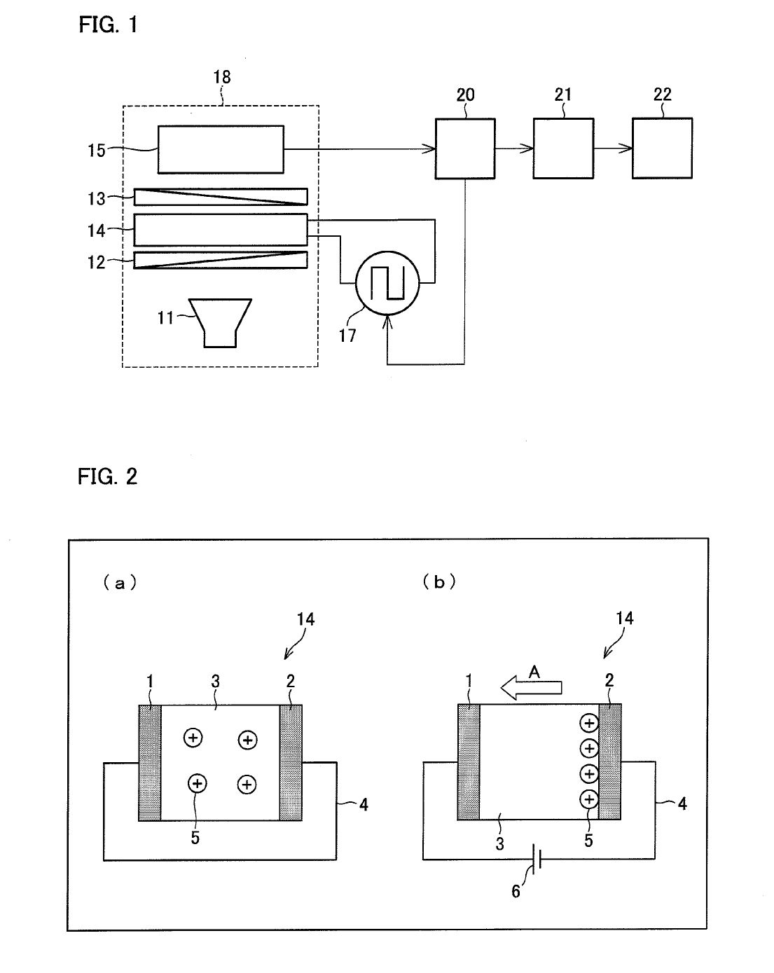

In FIG. 1, which will be described later, and (a) and (b) of FIG. 2, a direct-current voltage component caused due to such parasitic capacitance of the TFT is realized by an equivalent circuit. That is, an actual liquid crystal cell has a configuration equivalent to a configuration in which a voltage source 6 that applies the direct-current voltage component is provided, as illustrated in (b) of FIG. 2.

While a voltage is applied by the voltage source 6 to the either end of the liquid crystal cell 14, the ions 5 are unevenly distributed (drift) on one interface on a side of the alignment film 2, as illustrated in (b) of FIG. 2. When the ions 5 are unevenly distributed on the interface on the side of the alignment film 2 as such, a potential difference occurs between the alignment films 1 and 2. In this case, even after the voltage source 6 stops applying the direct-current voltage component (i.e., no direct-current voltage component is applied), a residual DC voltage occurs, as shown by an arrow A in (b) of FIG. 2. The residual DC voltage becomes a factor that induces screen burn-in. In view of this, it is important to reduce the residual DC voltage as much as possible.

As one of exemplary methods for measuring the residual DC voltage, a flicker elimination method is explained below. The following also describes an arrangement of an evaluation device of ion behavior in accordance with one embodiment of the present invention. The present embodiment only deals with the flicker elimination method. However, how to measure the residual DC voltage is not limited to the flicker elimination method. For example, a flicker reference method or the like method also can be used for measuring the residual DC voltage.

### Arrangement of Evaluation Device

FIG. 1 schematically illustrates an evaluation device of ion behavior. The evaluation device includes, as illustrated in FIG. 1, a light source 11, polarizers 12 and 13, a photodetector 15, a voltage oscillator (voltage application section) 17, a residual DC voltage measuring section 20, a rate measuring section (rate estimating section) 21, and an energy measuring section 22. The light source 11, the polarizers 12 and 13, and the photodetector 15 are provided in a chamber 18. Evaluation of the residual DC voltage is carried out such that the liquid crystal cell 14 is disposed between the polarizer 12 and the polarizer 13.

The light source 11 emits light toward the polarizers 12 and 13 between which the liquid crystal cell 14 is provided. The polarizers 12 and 13 are provided to form crossed Nicols.

The photodetector 15 detects transmitted light that is emitted from the light source 11 and transmitted through the liquid crystal cell 14 and the polarizers 12 and 13.

The voltage oscillator 17 can apply, to the liquid crystal cell 14, a rectangular wave voltage including a direct-current voltage component and a rectangular wave voltage including no direct-current voltage component. The evaluation device includes a timer (not shown) for measuring an application time during which the voltage oscillator 17 is applying a voltage to the liquid crystal cell 14.

The residual DC voltage measuring section 20 detects flicker from the transmitted light detected by the photodetector 15, per application time of the rectangular wave voltage including a direct-current offset, which is applied by the voltage oscillator 17, and then controls the voltage oscillator 17 to apply, to the liquid crystal cell 14, a rectangular wave voltage including a direct-current offset that eliminates the flicker to be detected. This is the flicker elimination method. The direct-current offset thus controlled is a residual DC voltage.

The rate measuring section 21 performs curve fitting on a relationship between (a) the residual DC voltage measured by the residual DC voltage measuring section 20 and (b) the application time of the rectangular wave voltage including a direct-current voltage component, which is applied by the voltage oscillator 17, by the following equation:

$$\begin{matrix}[ Math . 25 ] & \\ {V}_{rDC} ( t ) = ( \frac{q}{{C}_{LC}} ) ( \frac{{k}_{a} {n}_{f}}{{k}_{a} {n}_{f} + {k}_{d}} ) N [ 1 - exp \{ - ( {k}_{a} {n}_{f} + {k}_{d} ) t \} ] & Eq . ( 1 )\end{matrix}$$

Hereby, an adsorption rate coefficient and a desorption rate coefficient are found.

The energy measuring section 22 performs curve fitting on a relationship between the adsorption rate coefficient thus found and a temperature, by the following equation:

$$\begin{matrix}[ Math . 26 ] & \\ {k}_{a} {n}_{f} = {( {k}_{a} {n}_{f} )}_{0} exp ( - \frac{{E}_{a}}{kT} ) & Eq . ( 2 )\end{matrix}$$

Hereby, an adsorption energy is found.

Moreover, the energy measuring section 22 performs curve fitting on a relationship between the desorption rate coefficient and the temperature, by the following equation:

$$\begin{matrix}[ Math . 27 ] & \\ {k}_{d} = {( {k}_{d} )}_{0} exp ( - \frac{{E}_{d}}{kT} ) & Eq . ( 3 )\end{matrix}$$

Hereby, a desorption energy is obtained.

The chamber 18 controls a temperature of a set of the evaluation device, so as to control a temperature at the time of measuring a residual DC voltage. The chamber 18, therefore, allows measuring a residual DC voltage at each of a plurality of temperatures. Such a temperature control may be also performed, without using the chamber 18, in such a manner that the liquid crystal cell 14 is placed on a hot stage (not shown).

The residual DC voltage measuring section 20, the rate measuring section 21, and the energy measuring section 22 calculate, respectively, (i) the residual DC voltage, (ii) the adsorption rate coefficient and desorption rate coefficient, (iii) and the adsorption energy and desorption energy, per temperature changed by the chamber 18.

### Operation of Evaluation Device

The voltage oscillator 17 drives the liquid crystal cell 14 in such a manner that a rectangular wave voltage including a direct-current offset is applied to the liquid crystal cell 14 for a predetermined period of time, followed by applying thereto a rectangular wave voltage including no direct-current offset (the direct-current offset is 0). The driving in this manner causes the ions 5 to drift toward the alignment film 2, thereby causing flicker.

The residual DC voltage measuring section 20 adjusts the direct-current offset applied by the voltage oscillator 17 so that the flicker thus caused is not observed. As has been already mentioned above, such an adjusting method is called the flicker elimination method, and the direct-current offset thus adjusted is called residual DC voltage. The residual DC voltage measuring section 20 measures the residual DC voltage (direct-current offset voltage) per application time during which the rectangular wave voltage including a direct-current offset is being applied. Further, the residual DC voltage measuring section 20 plots the residual DC voltage thus measured, relative to the application time.

Further, the rate measuring section 21 performs curve fitting on a relationship, plotted as such, between the residual DC voltage and the application time, by use of Eq. (1). In this way, the rate measuring section 21 measures (estimates) an adsorption rate coefficient of ions that adsorb to an interface and a desorption rate coefficient of ions that desorb from the interface at each predetermined temperature.

The ions 5 present in the liquid crystal layer are affected by the direct-current offset and move toward an interface between the liquid crystal 3 and either of the alignment films 1 and 2. The ions 5 then adsorb onto the interface, ultimately. It is assumed that the adsorption to the interface is caused because an adsorption energy exceeds a diffusion energy of the ions 5. Further, it is assumed that the adsorption energy for the ions in the liquid crystal layer to adsorb to the interface is formed in balance with the diffusion energy (desorption energy). From this viewpoint, the adsorption energy is represented as Eq. (2).

Similarly, in regard to the ions 5 that are adsorbed on the interface, it is assumed that an energy for the ions 5 to desorb from the interface is formed in balance with an energy for the ions 5 to remain on the interface due to the direct-current offset. From the viewpoint, the desorption energy is represented as Eq. (3).

The energy measuring section 22 finds a relationship between a temperature and the adsorption rate coefficient that is found by the rate measuring section 21, and then performs curve fitting on the relationship by use of Eq. (2). In this way, the adsorption energy is obtained.

Further, the energy measuring section 22 finds a relationship between the temperature and the desorption rate coefficient that is found by the rate measuring section 21, and then performs curve fitting on the relationship by use of Eq. (3). In this way, the desorption energy is obtained.

More specifically, the energy measuring section 22 divides both sides of Eq. (2) by (kₐn_{f})₀, and then multiplies the both sides by a logarithm so as to obtain Eq. (4):

$$\begin{matrix}[ Math . 28 ] & \\ Ln \{ \frac{{k}_{a} {n}_{f}}{{( {k}_{a} {n}_{f} )}_{0}} \} = - \frac{{E}_{a}}{kT} & Eq . ( 4 )\end{matrix}$$

This equation is generally called Arrhenius plot. A plot according to the Arrhenius equation is an Arrhenius plot.

The energy measuring section 22 can find an adsorption energy according to a relationship between a logarithm of the adsorption rate coefficient and a reciprocal of an absolute temperature. Further, in accordance with a calculation similar to the above calculation, it is also possible to find a desorption energy.

That is, the adsorption energy can found by performing curve fitting, by use of Eq. (2), on the adsorption rate coefficient found by the curve fitting according to Eq. (1) performed by the rate measuring section 21. Further, the desorption energy can be found by performing curve fitting, by use of Eq. (3), on the desorption rate coefficient found by the curve fitting according to Eq. (1) performed by the rate measuring section 21.

Since the adsorption energy and the desorption energy can be found as such, it is possible to select (i) a liquid crystal material and an alignment film material, each of which reduces the adsorption energy and the desorption energy, and (ii) a liquid crystal display device (liquid crystal display element) which is constituted by a combination of the liquid crystal material and the alignment film material thus selected. By selecting such a liquid crystal display device (liquid crystal display element), it is possible to reduce the occurrence of screen burn-in.

As described above, a residual DC voltage is measured at each predetermined temperature, and a measurement result is curve-fitted according to Eq. (1), so as to find an adsorption rate coefficient and a desorption rate coefficient at the each predetermined temperature. Then, an adsorption energy and a desorption energy are found according to the Arrhenius plot performed on the adsorption rate coefficient and the desorption rate coefficient thus found. In this way, the adsorption energy and the desorption energy are obtained, thereby making it possible to manufacture a liquid crystal display device that can prevent the occurrence of screen burn-in in a wide temperature range.

That is, by accurately measuring (estimating) the adsorption energy and the desorption energy by finding, at a plurality of temperatures, unique parameters (the adsorption rate coefficient and the desorption rate coefficient) that are estimated by a liquid crystal material, an alignment film material, and a combination of these materials, it is possible to manufacture a liquid crystal display device (liquid crystal display element) in combination of a liquid crystal material and an alignment material each of which reduces the adsorption energy and the desorption energy. As a result, it is possible to manufacture a liquid crystal display device (liquid crystal display element) that can prevent screen burn-in.

Furthermore, the present embodiment can be expressed as follows.

It is preferable that the adsorption rate coefficient be made relatively small as compared to the desorption rate coefficient so that even in a case where the temperature changes, a proportion (balance) of the adsorption rate coefficient to the desorption rate coefficient is maintained. In view of this, it is preferable that respective slopes of a line indicative of the adsorption rate coefficient and a line indicative of the desorption rate coefficient be small where a lateral axis indicates a logarithm of the temperature and a vertical axis indicates logarithms of the adsorption rate coefficient and the desorption rate coefficient. When these slopes are small, it is possible to make the adsorption energy and the desorption energy small, too. That is, even in the case where the temperature changes, the adsorption energy and the desorption energy can be reduced.

The following describes how to derive Eq. (1). In the liquid crystal layer, there exist the ions 5 that do not involve the occurrence of the residual DC voltage, as illustrated in (a) of FIG. 2. When a direct electric field occurs in the liquid crystal layer in the presence of the ions 5, a generation rate (adsorbing ion density) nₐ(t) of adsorbing ions 5 is represented by the following equation:

$$\begin{matrix}[ Math . 29 ] & \\ {n}_{a} ( t ) = \frac{{k}_{a} {n}_{f}}{{k}_{a} {n}_{f} + {k}_{d}} N [ 1 - exp \{ - ( {k}_{a} {n}_{f} + {k}_{d} ) t \} ] & Eq . ( 5 )\end{matrix}$$

where kₐ is a rate coefficient of adsorbing the ions 5 in the liquid crystal layer to an interface, kd is a desorption rate coefficient of desorbing, from the interface, ions 5 that are adsorbed on the interface, and N is a density on an interface adsorption site.

Further, a relationship between the adsorbing ion density nₐ(t) and the residual DC voltage is represented by the following equation:

[Math. 30]

Q=nₐ(t)q=C_{LC}V_{rDC}(t) Eq. (6)

In Eq. (6), q is elementary charge, C_{LC} is capacitance of a liquid crystal layer, and V_{rDC}(t) is a residual DC voltage at a time t. The equation Eq. (1) can be derived from Eq. (5) and Eq. (6).

### Embodiment 2

The present embodiment describes only points that are different from Embodiment 1.

An evaluation device for evaluating ion behavior used in the present embodiment is the one that is used in Embodiment 1.

In Embodiment 1, initially, a rectangular wave voltage including a direct-current offset is applied to a liquid crystal cell, and then, a rectangular wave including no direct-current offset is applied to the liquid crystal cell, so as to obtain an adsorption rate coefficient and a desorption rate coefficient. After that, based on the adsorption rate coefficient and the desorption rate coefficient, an adsorption energy and a desorption energy are obtained. Thus, parameters unique to a liquid crystal material and an alignment film material are obtained for the purpose of preventing screen burn-in.

In the meantime, in the present embodiment, initially, a rectangular wave voltage including a direct-current offset is applied to a liquid crystal cell. After that, the liquid crystal cell is caused to be open-circuit, and two relaxation rate coefficients are found. Then, based on these relaxation rate coefficients, two relaxation energies are found. In this way, parameters unique to the liquid crystal material and the alignment film material are obtained for the purpose of preventing the screen burn-in. Here, the “open-circuit” means, for example, a condition in which no wiring line 4 is provided, or a condition in which a high-resistance dielectric is present in the wiring line 4, in (a) and (b) of FIG. 2.

In order to relax the residual DC voltage, the evaluation device used in Embodiment 1 is used.

The measurement of relaxation of the residual DC voltage is performed such that ions 5 adsorbed on an interface is relaxed by causing the liquid crystal cell 14 to be open-circuit, and then the residual DC voltage is measured by a residual DC voltage measuring section 20 at appropriate time intervals. In this measurement, assume that among a plurality of ionic components adsorbed on the interface, two types of ions (R1 component and R2 component) are present such that a proportion thereof is A:1−A. As the grounds for the assumption, there may be, for example, presence of a plurality of impurities, and presence of a plurality of adsorption sites on an alignment film surface. The present embodiment deals with two types of relaxation components (ionic components). However, this is merely one example, and three or more relaxation components may be examined.

### Arrangement

The residual DC voltage measuring section 20 applies a rectangular wave voltage including a direct-current offset to a liquid crystal cell, and then controls a voltage oscillator 17 so as to cause the liquid crystal cell to be open-circuit.

A rate measuring section 21 finds respective relaxation rate coefficients of ionic relaxation from the interface, in regard to relaxation components R1 and R2. The relaxation components are ionic components that are adsorbed on an alignment film interface.

An energy measuring section 22 finds respective relaxation energies based on the respective relaxation rate coefficients thus found as above.

The other arrangements are the same as those in Embodiment 1.

The relaxation of ions adsorbed on the interface at the time of causing the liquid crystal cell 14 to be open-circuit can be represented by the following equation Eq. (7):

$$\begin{matrix}[ Math . 31 ] & \\ {n}_{a} ( t ) = {n}_{n} ( 0 ) [ A exp ( - \frac{t}{{τ}_{R 1}} ) + ( 1 - A ) exp ( - \frac{t}{{τ}_{R 2}} ) ] & Eq . ( 7 )\end{matrix}$$

In Eq. (7), τ_{R1} and τ_{R2} indicates ionic relaxation times of the relaxation components R1 and R2, respectively. Further, nₐ(0) is a density of ions that are adsorbed on the interface right after the relaxation. The relaxation times τ_{R1} and τ_{R2} of the ions adsorbed on the interface can be expressed as shown in Eq. (7). Therefore, from Eq. (7) and Eq. (6), the relaxation of the residual DC voltage can be represented by the following equation Eq. (8):

$$\begin{matrix}[ Math . 32 ] & \\ {V}_{{rDC}^{( t )}} = ( \frac{q}{{C}_{LC}} ) {n}_{a} ( 0 ) [ A exp ( - \frac{t}{{τ}_{R 1}} ) + ( 1 - A ) exp ( - \frac{t}{{τ}_{R 2}} ) ] & Eq . ( 8 )\end{matrix}$$

### Operation

The rate measuring section 21 finds respective relaxation rate coefficients (1/τ_{R1} (first relaxation rate coefficient) and 1/τ_{R2} (second relaxation rate coefficient)) of the relaxation component R1 and the relaxation component R2 by performing curve fitting, according to Eq. (8), on a relationship, plotted with several points, between the residual DC voltage and an open-circuit time.

Relaxation of the ions adsorbed on the interface is caused when an energy for relaxing ions from the interface exceeds an energy for ions to remain on the interface in the open-circuit condition. Therefore, temperature dependencies of the first and second relaxation coefficients (1/τ_{R1} and 1/τ_{R2}) of the respective ions are represented, respectively, by the following equations:

$$\begin{matrix}[ Math . 33 ] & \\ \frac{1}{{τ}_{R 1}} = {( \frac{1}{{τ}_{R 1}} )}_{0} exp ( - \frac{{E}_{R 1}}{k T} ) & Eq . ( 9 ) \\ [ Math . 34 ] & \\ \frac{1}{{τ}_{R 2}} = {( \frac{1}{{τ}_{R 2}} )}_{0} exp ( - \frac{{E}_{R 2}}{k T} ) & Eq . ( 10 )\end{matrix}$$

The energy measuring section 22 finds a relaxation energy (first relaxation energy) by performing curve fitting according to Eq. (9) based on the first relaxation rate coefficient (1/τ_{R1}).

Further, the energy measuring section 22 finds a relaxation energy (second relaxation energy) by performing curve fitting according to Eq. (10) based on the second relaxation rate coefficient (1/τ_{R2}).

As such, the relaxation energies E_{R1} and E_{R2} are estimated in such a manner that (i) relaxation of the residual DC voltage in an open-circuit condition is measured at a predetermined temperature, (ii) a measurement result is curve-fitted according to Eq. (8) so as to find two relaxation rate coefficients for the predetermined temperature, and (iii) these relaxation rate coefficients are subjected to the Arrhenius plot.

In this way, the relaxation energies E_{R1} and E_{R2} are found by the curve fitting according to Eq. (9) and Eq. (10), respectively, which are performed by the energy measuring section 22.

Since the two relaxation energies can be found as such, it is possible to select a liquid crystal material and an alignment film material each of which reduces the relaxation energies, thereby making it possible to select a liquid crystal display device (liquid crystal display element) that is manufactured in combination of such a liquid crystal material and such an alignment material. By selecting such a liquid crystal display device (liquid crystal display element), it is possible to reduce the occurrence of screen burn-in.

### Example 1

A plurality of liquid crystal cells (cell gap: 5 μm) in a homogeneous alignment were manufactured with the use of a liquid crystal material A and an alignment film material B, in order to evaluate their temperature dependencies. That is, the liquid crystal cells were prepared for respective temperatures. In the present example, the residual DC voltage was measured at 4 temperatures, 25° C., 40° C., 55° C., and 70° C., as one example, and therefore, 4 liquid crystal cells were prepared. After the alignment film material B was deposited on 2 substrates, the 2 substrates were subjected to a rubbing process. Then, the 2 substrates were attached to each other. Finally, the liquid crystal material A was injected therebetween.

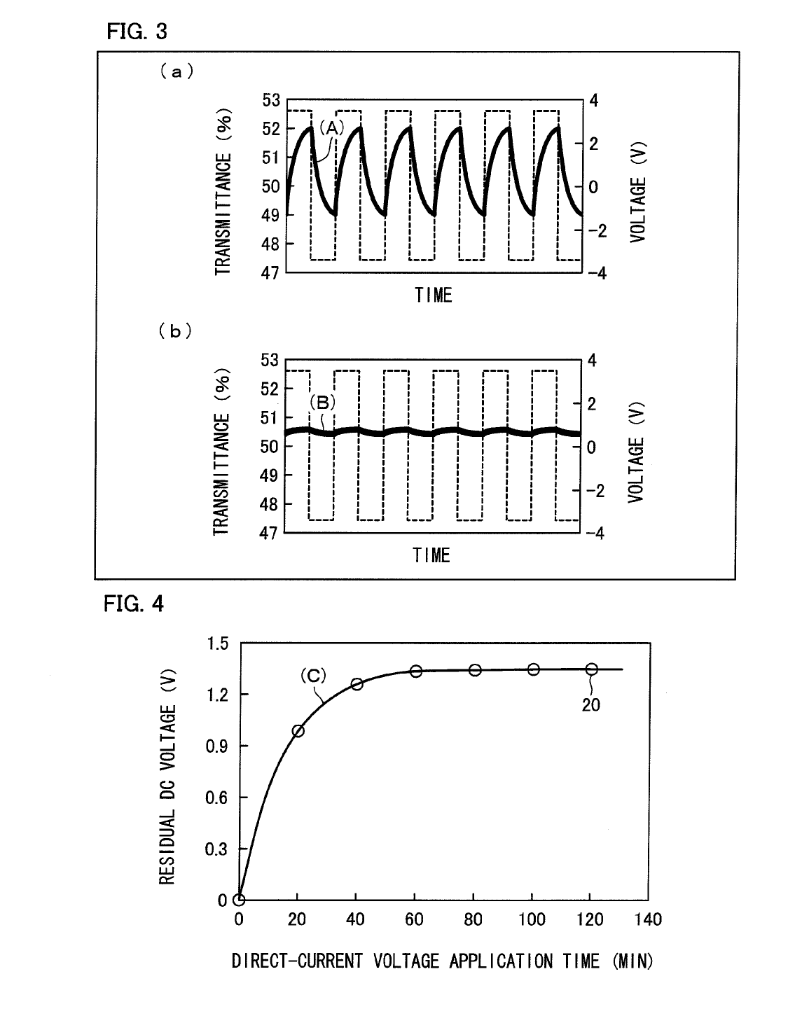

With the use of the evaluation device, a residual DC voltage was measured by the flicker elimination method. An application voltage to be applied to the liquid crystal cell was such that, as one example, a rectangular wave voltage of 30 Hz and 3.4 V (shown by a dotted line in (a) and (b) of FIG. 3) was applied and a direct-current offset (V) of 5 V was superimposed thereon. The application voltage 3.4 V as the rectangular wave voltage is a voltage value at which a transmittance (%) is about 50% in a V-T characteristic (Voltage-Transmittance characteristic).

After the voltage was applied to the liquid crystal cell at 25° C. for 20 minutes, the direct-current offset was set to 0 V, and the rectangular wave voltage was set to 3.4 V (30 Hz). A wave of transmitted light at this time is shown in (a) of FIG. 3. A wave (A) shown in (a) of FIG. 3 indicates a relationship between time and a respective of the transmittance (%) and the direct-current offset (V). As shown by the wave (A) in (a) of FIG. 4, notable flicker was observed.

Subsequently, the direct-current offset (V) was adjusted so that no flicker was observed as shown by a wave (B) in (b) of FIG. 3. At this time, a direct-current offset of 0.92 V was required. For this reason, the residual DC voltage was 0.92 V under this condition.

The residual DC voltage was evaluated about every 20 minutes for 2 hours in this manner. That is, the residual DC voltage was measured at each of the following application times of the direct-current offset: 20 min, 40 min, 60 min, 80 min, 100 min, and 120 min.

During the measurement, a relationship between the residual DC voltage (V) and the application time (min) of the direct-current offset was actually measured and plotted as shown by a referential numeral 20 in FIG. 4.

Further, curve fitting according to Eq. (1) was performed on the result of the plotting. A result of the curve fitting is shown by a solid line (C) in FIG. 4. The result of the actual measurement and the result of the curve fitting coincide well with each other.

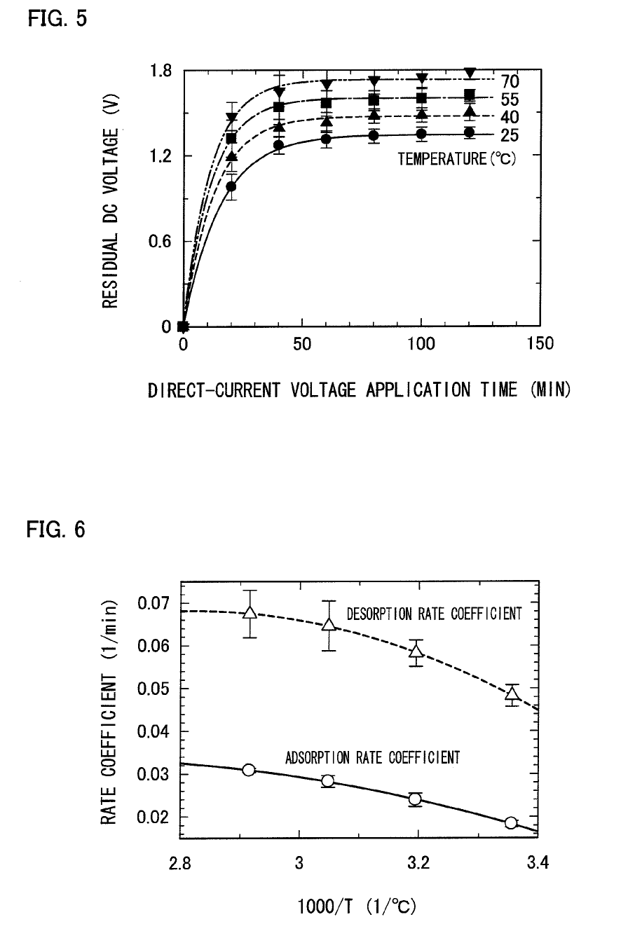

Furthermore, actual measurement results of the residual DC voltage (V) and results of curve fitting at the other temperatures except 25° C. (i.e., at 40° C., 55° C., and 70° C.) are also shown in FIG. 5.

The curve fitting according to Eq. (1) is such that fitting is performed by a least-square method so that a standard deviation takes a minimum value. The standard deviation in the curve fitting of the residual DC voltage at each of the temperatures is shown in [Table 1].

TABLE 1

| | 25° C. | 40° C. | 55° C. | 70° C. |
|---|---|---|---|---|
| Standard Deviation | 0.00927 | 0.01881 | 0.01305 | 0.02656 |
| According to | | | | |
| Least-Square Method | | | | |

Further, an adsorption rate coefficient and a desorption rate coefficient were found at each of the temperatures by performing the curve fitting according to Eq. (1). The results are shown in FIG. 6.

As shown in FIG. 6, the adsorption rate coefficient and the desorption rate coefficient exhibit curves with respect to a change in temperature.

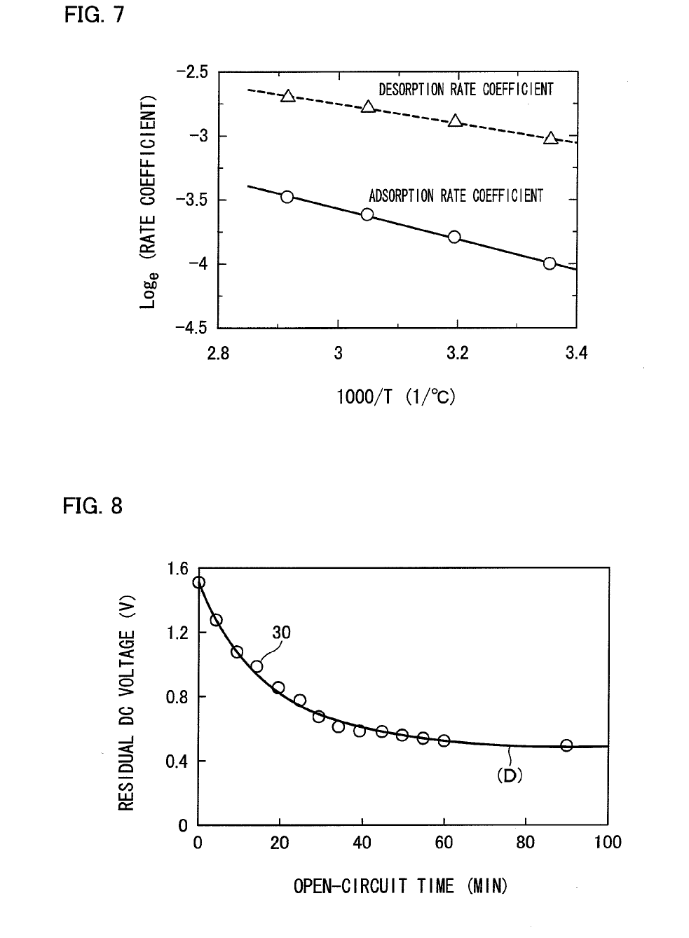

This demonstrates that an adsorption process of ions onto an interface and a desorption process of ions from the interface occur according to the Boltzmann distribution law. Each of the plots in FIG. 6 was subjected to the Arrhenius plot. Results of the Arrhenius plot are shown in FIG. 7. The results according to the Arrhenius plot exhibit a straight line. This demonstrates that an adsorption energy and an desorption energy can be found respectively by Eq. (2) and Eq. (3). The adsorption energy was 0.10 eV, and the desorption energy was 0.11 eV.

Standard deviations of the curve fitting at the time of forming the Arrhenius plot are shown in [Table 2]

TABLE 2

| | Adsorption | Desorption |
|---|---|---|
| | Rate | Rate |
| | Coefficient | Coefficient |
| Standard Deviation | 0.00854 | 0.01731 |
| According to | | |
| Least-Square Method | | |

From these results, it is demonstrated that when ions are present in a liquid crystal layer of a liquid crystal display device and a direct-current offset is applied to the liquid crystal layer, adsorption (process) of ions onto an interface and desorption (process) of ions from the interface are caused according to the Boltzmann distribution law.

### Example 2

A plurality of liquid crystal cells (cell gap: 5 μm) in a homogeneous alignment were manufactured with the use of a liquid crystal material A and an alignment film material B, in order to evaluate their temperature dependencies. That is, the liquid crystal cells were prepared for respective temperatures. In the present example, the residual DC voltage was measured at 4 temperatures, 25° C., 40° C., 55° C., and 70° C., as one example, and therefore, 4 liquid crystal cells were prepared. After the alignment film material B was deposited on 2 substrates, the 2 substrates were subjected to a rubbing process. Then, the 2 substrates were attached to each other. Finally, the liquid crystal material A was injected therebetween.

With the use of the evaluation device, a residual DC voltage was measured by the flicker elimination method. An application voltage to be applied to the liquid crystal cell was such that, as one example, a rectangular wave voltage of 30 Hz and 3.4 V (shown by a dotted line in (a) and (b) of FIG. 3) was applied and a direct-current offset (V) of 5 V was superimposed thereon. The application voltage was applied for 2 hours. The application voltage 3.4 V as the rectangular wave voltage is a voltage value at which a transmittance (%) is about 50% in a V-T characteristic (Voltage-Transmittance characteristic).

After the rectangular wave voltage on which the direct-current offset voltage was superimposed were applied for 2 hours, the liquid crystal cell was caused to be open-circuit. Under this condition, relaxation of a residual DC voltage was observed. Measurement temperatures were 25° C., 40° C., 55° C., and 70° C.

The relaxation of the residual DC voltage was evaluated for 1.5 hours in this manner. During the evaluation, a relationship between the residual DC voltage (V) and time (open-circuit time; min) was actually measured and plotted as shown by a referential numeral 30 in FIG. 8. Further, curve fitting according to Eq. (8) was performed on the result of the plotting. A result of the curve fitting is shown by a solid line (D) in FIG. 8.

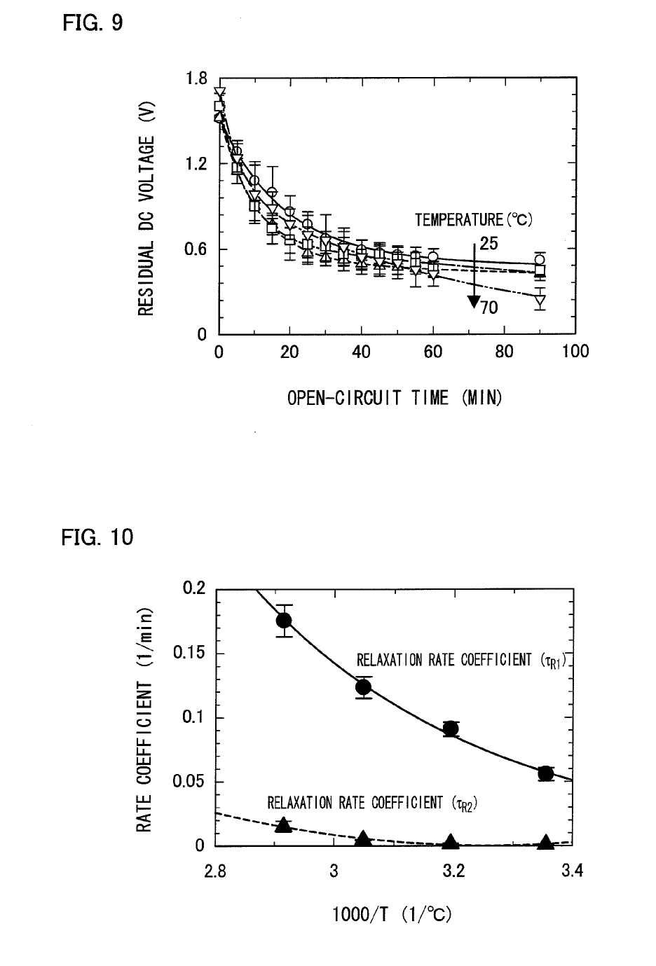

The result of the actual measurement and the result of the curve fitting coincide well with each other. Furthermore, actual measurement results of the relaxation of the residual DC voltage and results of curve fitting at respective temperatures are shown in FIG. 9. Further, temperature dependencies of two relaxation rate coefficients (τ_{R1} and τ_{R2}) at each of the temperatures are shown in FIG. 10. [Table 3] shows a standard deviation in the curve fitting at each of the temperatures in regard to the relaxation of the residual DC voltage.

TABLE 3

| | 25° C. | 40° C. | 55° C. | 70° C. |
|---|---|---|---|---|
| Standard Deviation | 0.02112 | 0.00779 | 0.01711 | 0.01227 |
| According to | | | | |
| Least-Square Method | | | | |

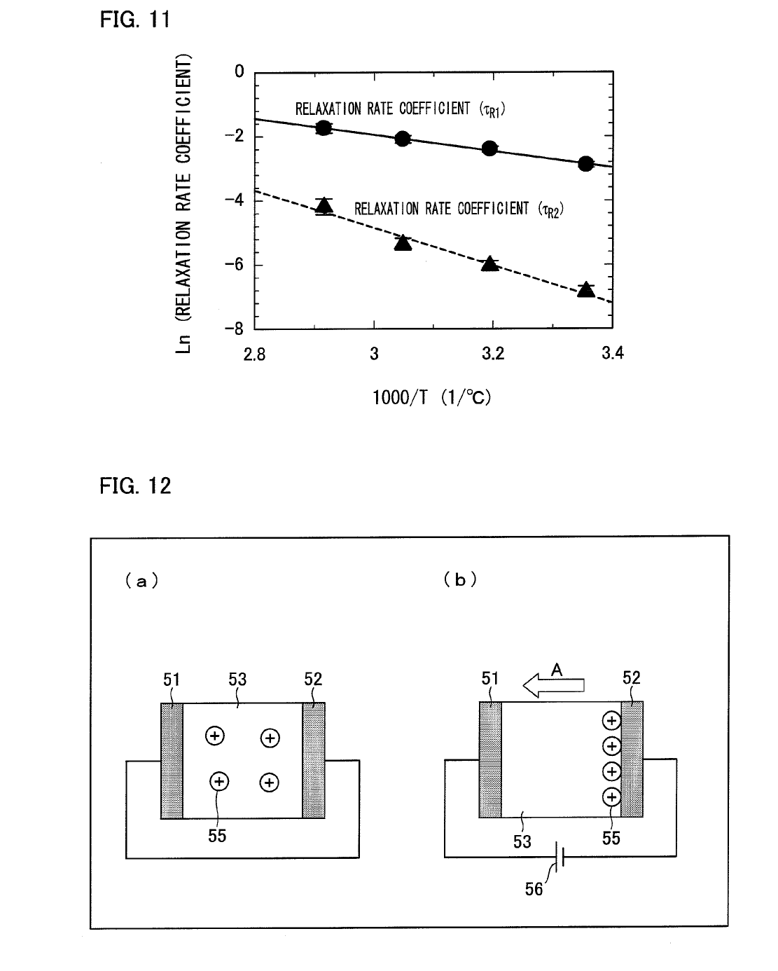

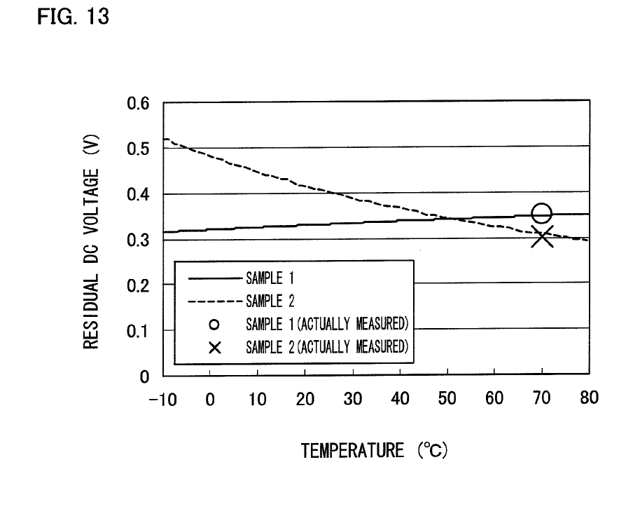

As shown in FIG. 10, both of the relaxation rate coefficients (τ_{R1} and τ_{R2}) exhibit curves with respect to a change in temperature. This demonstrates that the relaxation of the ions from the interface occurs according to the Boltzmann distribution law. Each of the plots in FIG. 10 was subjected to the Arrhenius plot. The results are shown in FIG. 11. The results according to the Arrhenius plot exhibit a straight line. This demonstrates that relaxation energies (E_{R1} and E_{R2}) of the ions adsorbed on the interface can be found according to Eq. (9) and Eq. (10), respectively. The relaxation energies (E_{R1} and E_{R2}) are, respectively, 0.22 ev and 0.52 ev. [Table 4] shows standard deviations of the curve fitting at the time of forming the Arrhenius plot.

TABLE 4

| | Adsorption | Desorption |
|---|---|---|
| | Rate | Rate |
| | Coefficient | Coefficient |
| Standard Deviation | 0.01126 | 0.01950 |
| According to | | |
| Least-Square Method | | |

From these results, it is demonstrated that after a direct-current offset voltage is applied to a liquid crystal display device for a predetermined period of time, a relaxation process of ions adsorbed on the interface are caused according to the Boltzmann distribution law.

In order to restrain the occurrence of screen burn-in in a wide temperature range by decreasing the residual DC voltage, the following points are necessary in various combinations of a liquid crystal material and an alignment film material:

(1) to clarify an adsorption rate coefficient of impurity ions in the liquid crystal layer and a desorption (diffusion) rate coefficient of impurity ions adsorbed on an interface between a liquid crystal and an alignment film, each at the time of applying a DC offset voltage;
(2) to clarify respective temperature dependencies of the adsorption rate coefficient and the desorption rate coefficient;
(3) to select, based on the temperature dependencies obtained by (2), a combination condition of materials that allows a residual DC voltage to be low in a temperature range employed by a liquid crystal display device.

Especially, among the series of flows (1) through (3), it is most important to clarify the respective temperature dependencies of the adsorption rate coefficient and the desorption rate coefficient.

The present invention is not limited to the description of the embodiments above, but may be altered by a skilled person within the scope of the claims. An embodiment based on a proper combination of technical means disclosed in different embodiments is encompassed in the technical scope of the present invention.

Finally, the blocks of the evaluation device may be realized by way of hardware or software as executed by a CPU as follows.

The residual DC voltage evaluation device includes a CPU (central processing unit) and memory devices (memory media). The CPU (central processing unit) executes instructions in control programs realizing the functions. The memory devices include a ROM (read only memory) which contains programs, a RAM (random access memory) to which the programs are loaded, and a memory containing the programs and various data. The objective of the present invention can also be achieved by mounting to the residual DC voltage evaluation device a computer-readable storage medium containing control program code (executable program, intermediate code program, or source program) for the residual DC voltage evaluation device, which is software realizing the aforementioned functions, in order for the computer (or CPU, MPU) to retrieve and execute the program code contained in the storage medium.

The storage medium may be, for example, a tape, such as a magnetic tape or a cassette tape; a magnetic disk, such as a Floppy (Registered Trademark) disk or a hard disk, or an optical disk, such as CD-ROM/MO/MD/DVD/CD-R; a card, such as an IC card (memory card) or an optical card; or a semiconductor memory, such as a mask ROM/EPROM/EEPROM/flash ROM.

The residual DC voltage evaluation device may be arranged to be connectable to a communications network so that the program code may be delivered over the communications network. The communications network is not limited in any particular manner, and may be, for example, the Internet, an intranet, extranet, LAN, ISDN, VAN, CATV communications network, virtual dedicated network (virtual private network), telephone line network, mobile communications network, or satellite communications network. The transfer medium which makes up the communications network is not limited in any particular manner, and may be, for example, wired line, such as IEEE 1394, USB, electric power line, cable TV line, telephone line, or ADSL line; or wireless, such as infrared radiation (IrDA, remote control), Bluetooth (registered trademark), 802.11 wireless, HDR, mobile telephone network, satellite line, or terrestrial digital network. The present invention encompasses a computer data signal which is embedded in a carrier wave and in which the program code is embodied in the form of electronic transmission.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

### INDUSTRIAL APPLICABILITY

The evaluation method of the present invention for evaluating ion behavior and the evaluation device of the present invention for evaluating ion behavior can be used for selection of a liquid crystal material, selection of an alignment film material, and selection of a combination of these materials, in a liquid crystal display device.

1-10. (canceled)

11. An evaluation method comprising:
a measuring step of measuring a residual DC voltage occurring after a voltage including a direct-current voltage component is applied to a liquid crystal cell including alignment films and a liquid crystal sandwiched therebetween;
an evaluation step of evaluating behavior of the ions in the liquid crystal cell based on the residual DC voltage thus measured in the measuring step.

12. The evaluation method as set forth in claim 11, wherein:
the measuring step is a step of measuring, at each of a predetermined plurality of temperatures, a plurality of combinations of (i) an application time during which the voltage including a direct-current voltage component is applied to the liquid crystal cell and (ii) the residual DC voltage occurring after the voltage including a direct-current voltage component is applied to the liquid crystal cell, and
the evaluation step includes:
a first estimation step of estimating, for the each of the predetermined plurality of temperatures, an adsorption rate coefficient of ions that adsorb to an interface between the liquid crystal and one of the alignment films, and a desorption rate coefficient of ions that desorb from the interface, based on the plurality of combinations of the application time and the residual DC voltage at the each of the predetermined plurality of temperatures; and
a second estimation step of estimating an adsorption energy of the ions that adsorb to the interface, based on the adsorption rate coefficients of the predetermined plurality of temperatures, and a desorption energy of the ions that desorb from the interface, based on the desorption rate coefficients of the predetermined, plurality of temperatures.

13. The evaluation method as set, forth in claim 11, wherein:
the measuring step is a step of measuring, at each of a predetermined plurality of temperatures, a time-dependence of the residual DC voltage that changes over time after the liquid crystal cell is caused to be open-circuit, and
the evaluation step includes:
a first estimation step of estimating, for the each of the predetermined plurality of temperatures, a first relaxation rate coefficient and a second relaxation rate coefficient from among a plurality of relaxation rate coefficients of ions relaxed from an interface between the liquid crystal and one of the alignment films, based on the time-dependence of the residual DC voltage that changes over time after the liquid crystal cell is caused to be open-circuit; and
a second estimation step of estimating a first relaxation energy based on the first relaxation rate coefficients of the predetermined plurality of temperatures, and a second relaxation energy based on the second relaxation rate coefficients of the predetermined plurality of temperatures.

14. The evaluation method as set forth in claim 12, wherein:
the measuring step is a step of measuring, at the each of the predetermined plurality of temperatures, a plurality of combinations of (i) the application time t during which the voltage including a direct-current voltage component is applied to the liquid crystal cell and (ii) the residual DC voltage V_{rDC} occurring after the application of the voltage to the liquid crystal cell,
the first estimation step is a step of estimating (a) the adsorption rate coefficient kₐ·n_{f} of the ions that adsorb to the interface between the liquid crystal and the one of the alignment films, and (b) the desorption rate coefficient k_{d} of the ions that desorb from the interface, by performing curve fitting according to the following equation:
$${V}_{{rDC}^{( t )}} = ( \frac{q}{{C}_{LC}} ) ( \frac{{k}_{a} {n}_{f}}{{k}_{a} {n}_{f} + {k}_{d}} ) N [ 1 - exp \{ - ( {k}_{a} {n}_{f} + {k}_{d} ) t \} ] \qquad [ Math . 1 ]$$
the adsorption rate coefficient kₐ·n_{f} and the desorption rate coefficient k_{d} being estimated, for the each of the predetermined plurality of temperatures, based on the plurality of combinations of the application time t and the residual DC voltage V_{rDC} at the each of the predetermined plurality of temperatures, and
the second estimation step is a step of estimating (c) the adsorption energy Eₐ of the ions that adsorb to the interface, based on the adsorption rate coefficients kₐ·n_{f} of the predetermined plurality of temperatures, the adsorption energy kₐ·n_{f} being estimated by performing curve fitting according to the following equation:
$${k}_{a} {n}_{f} = {( {k}_{a} {n}_{f} )}_{0} exp ( - \frac{{E}_{a}}{kT} ) \qquad [ Math . 2 ]$$
and (d) the desorption energy E_{d} of the ions that desorb from the interface, based on the desorption rate coefficients k_{d} of the predetermined plurality of temperatures, the desorption energy E_{d} being estimated by performing curve fitting according to the following equation:
$${k}_{d} = {( {k}_{d} )}_{0} exp ( - \frac{{E}_{d}}{kT} ) \qquad [ Math . 3 ]$$
wherein, in each of the equations, kₐ is a rate coefficient of ions, in a liquid crystal layer, that adsorb to the interface; n_{f} is an ion density in the liquid crystal layer; q is elementary charge; C_{LC} is capacitance of the liquid crystal layer; k is a Boltzmann constant; and T is an absolute temperature.

15. The evaluation method as set forth in claim 13, wherein:
the measuring step is a step of measuring, at the each of the predetermined plurality of temperatures, the time-dependence of the residual DC voltage V_{rDC} that changes over time after the liquid crystal cell is caused to be open-circuit,
the first estimation step is a step, of estimating the first relaxation rate coefficient 1/τ_{R1} and the second relaxation rate coefficient 1/τ_{R2} from among the plurality of relaxation rate coefficients of the ions relaxed from the interface between the liquid crystal and the one of the alignment films, by performing curve fitting according to the following equation:
$${V}_{{rDC}^{( t )}} = ( \frac{q}{{C}_{LC}} ) {n}_{a} ( 0 ) [ A exp ( - \frac{t}{{τ}_{R 1}} ) + ( 1 - A ) exp ( - \frac{t}{{τ}_{R 2}} ) ] \qquad [ Math . 4 ]$$
the first relaxation rate coefficient 1/τ_{R1} and the second relaxation rate coefficient 1/τ_{R2} being estimated, for the each of the predetermined plurality of temperatures, based on the time-dependence of the residual DC voltage that changes over time after the liquid crystal cell is caused to be open-circuit, and
the second estimation step is a step of estimating (i) the first relaxation energy E_{R1} based on the first relaxation rate coefficients 1/τ_{R1} of the predetermined plurality of temperatures, the first relaxation energy E_{R1} being estimated by performing curve fitting according to the following equation:
$$\frac{1}{{τ}_{R 1}} = {( \frac{1}{{τ}_{R 1}} )}_{0} exp ( - \frac{{E}_{R 1}}{k T} ) \qquad [ Math . 5 ]$$
and (ii) the second relaxation energy E_{R2} based on the second relaxation rate coefficients 1/τ_{R2} of the predetermined plurality of temperatures, the second relaxation energy E_{R2} being estimated by performing curve fitting according to the following equation:
$$\frac{1}{{τ}_{R 2}} = {( \frac{1}{{τ}_{R 2}} )}_{0} exp ( - \frac{{E}_{R 2}}{k T} ) \qquad [ Math . 6 ]$$
wherein, in each of the equations, t is time elapsing after the liquid crystal cell is caused to be open-circuit; q is elementary charge; C_{LC} is capacitance of a liquid crystal layer; k is a Boltzmann constant; E_{R1} is the first relaxation energy; nₐ(0) is a density of adsorbing ions that are adsorbed on an interface right after the liquid crystal cell is caused to be open-circuit; A is a ratio of ions having the first relaxation rate coefficient; 1−A is a ratio of ions having the second relaxation rate coefficient; and T is an absolute temperature.

16. The evaluation method as set forth in claim 11, wherein:
the residual DC voltage is measured by a flicker elimination method.

17. The evaluation method as set forth in claim 14, wherein:
the curve fittings are performed by a least-square method so that a standard deviation takes a minimum value.

18. The evaluation method as set forth in claim 15, wherein:
the curve fittings are performed by a least-square method so that a standard deviation takes a minimum value.

19. An evaluation device for evaluating ion behavior, comprising:
a voltage application section for applying a voltage including a direct-current voltage component to a liquid crystal cell including alignment films and a liquid crystal sandwiched therebetween;
a residual DC voltage measuring section for measuring a residual DC voltage occurring after the voltage including a direct-current voltage component is applied to the liquid crystal cell; and
an evaluation section for evaluating behavior of ions in the liquid crystal cell based on the residual DC voltage thus measured by the residual DC voltage measuring section.

20. The evaluation device as set forth in claim 19, wherein:
the voltage application section applies, to the liquid crystal cell, the voltage including a direct-current voltage component and a voltage including no direct-current voltage component,
the residual DC voltage measuring section measures, at each of a predetermined plurality of temperatures, a plurality of combinations of (i) an application time t during which the voltage including a direct-current voltage component is applied to the liquid crystal cell and (ii) the residual DC voltage V_{rDC} occurring after the voltage including a direct-current voltage component is applied to the liquid crystal cell, and
the evaluation section includes:
a rate estimating section for estimating (a) an adsorption rate coefficient kₐ·n_{f} of ions that adsorb to an interface between the liquid crystal and one of the alignment films and (b) a desorption rate coefficient k_{d} of ions that desorb from the interface, by performing curve fitting according to the following equation:
$${V}_{{rDC}^{( t )}} = ( \frac{q}{{C}_{LC}} ) ( \frac{{k}_{a} {n}_{f}}{{k}_{a} {n}_{f} + {k}_{d}} ) N [ 1 - exp \{ - ( {k}_{a} {n}_{f} + {k}_{d} ) t \} ] \qquad [ Math . 7 ]$$
the rate estimating section estimating the adsorption rate coefficient kₐ·n_{f} and the desorption rate coefficient k_{d}, for the each of the predetermined, plurality of temperatures, based on the plurality of combinations of the application time t and the residual DC voltage V_{rDC} at the each of the predetermined plurality of temperatures; and,
an energy estimating section for estimating (c) an adsorption energy Eₐ of the ions that adsorb to the interface, based on the adsorption rate coefficients kₐ·n_{f} of the predetermined plurality of temperatures, by performing curve fitting according to the following equation:
$${k}_{a} {n}_{f} = {( {k}_{a} {n}_{f} )}_{0} exp ( - \frac{{E}_{a}}{kT} ) \qquad [ Math . 8 ]$$
and (d) a desorption energy E_{d} of the ions that desorb from the interface, based on the desorption rate coefficients k_{d} of the predetermined plurality of temperatures, by performing curve fitting according to the following equation:
$${k}_{d} = {( {k}_{d} )}_{0} exp ( - \frac{{E}_{d}}{kT} ) \qquad [ Math . 9 ]$$
wherein, in each of the equations, kₐ is a rate coefficient of ions, in a liquid crystal layer, that adsorb to the interface; n_{f} is an ion density in the liquid crystal layer; q is elementary charge; C_{LC} is capacitance of the liquid crystal layer; k is a Boltzmann constant; and T is an absolute temperature.

21. The evaluation device as set forth in claim 19, wherein:
the residual DC voltage measuring section measures, at each of a predetermined plurality of temperatures, a time-dependence of the residual DC voltage V_{rDC} that changes over time after the liquid crystal cell is caused to be open-circuit, and
the evaluation section includes:
a rate estimating section for estimating a first relaxation rate coefficient 1/τ_{R1} and a second relaxation rate coefficient 1/τ_{R2} from among a plurality of relaxation rate coefficients of ions relaxed from an interface between the liquid crystal and one of the alignment films, by performing curve fitting according to the following equation:
$${V}_{{rDC}^{( t )}} = ( \frac{q}{{C}_{LC}} ) {n}_{a} ( 0 ) [ A exp ( - \frac{t}{{τ}_{R 1}} ) + ( 1 - A ) exp ( - \frac{t}{{τ}_{R 2}} ) ] \qquad [ Math . 10 ]$$
the rate estimating section estimating the first relaxation rate coefficient 1/τ_{R1} and the second relaxation rate coefficient 1/τ_{R2}, for the each of the predetermined plurality of temperatures, based on the time-dependence of the residual DC voltage V_{rDC} that changes over time after the liquid crystal cell is caused to be open-circuit; and
an energy estimating section for estimating (a) a first relaxation energy E_{R1} based on the first relaxation rate coefficients 1/τ_{R1} of the predetermined plurality of temperatures, by performing curve fitting according to the following equation:
$$\frac{1}{{τ}_{R 1}} = {( \frac{1}{{τ}_{R 1}} )}_{0} exp ( - \frac{{E}_{R 1}}{k T} ) \qquad [ Math . 11 ]$$
and (b) a second relaxation energy E_{R2} based on the relaxation rate coefficients 1/τ_{R2} of the predetermined plurality of temperatures, by performing curve fitting according to the following equation:
$$\frac{1}{{τ}_{R 2}} = {( \frac{1}{{τ}_{R 2}} )}_{0} exp ( - \frac{{E}_{R 2}}{k T} ) \qquad [ Math . 12 ]$$
wherein, in each of the equations, t is time elapsing after the liquid crystal cell is caused to be open-circuit; q is elementary charge; C_{LC} is capacitance of a liquid crystal layer; k is a Boltzmann constant; E_{R1} is the first relaxation energy; nₐ(0) is a density of adsorbing ions that are adsorbed on the interface right after the liquid crystal layer is caused to be open-circuit; A is a ratio of ions having the first relaxation rate coefficient; 1−A is a ratio of ions having the second relaxation rate coefficient; and T is an absolute temperature.

22. The evaluation device as set forth in claim 19, wherein:
the residual DC voltage is measured by a flicker elimination method.

23. The evaluation device as set forth in claim 20, wherein:
the curve fittings are performed by a least-square method so that a standard deviation takes a minimum value.

24. The evaluation device as set forth in claim 21, wherein:
the curve fittings are performed by a least-square method so that a standard deviation takes a minimum value.

25. A manufacturing method of a liquid crystal display device, said method comprising:
a measuring step of measuring a residual DC voltage occurring after a voltage including a direct-current voltage component is applied to a liquid crystal cell including alignment films and a liquid crystal sandwiched therebetween;
an evaluation step of evaluating behavior of ions in the liquid crystal cell based on the residual DC voltage thus measured in the measuring step; and
a selecting step of selecting a material of the liquid crystal and a material of the alignment films in accordance with the behavior of the ions thus evaluated in the evaluation step.

26. The manufacturing method as set forth in claim 25, wherein:
the measuring step is a step of measuring, at each of a predetermined plurality of temperatures, a plurality of combinations of (i) an application time during which a voltage including a direct-current voltage component is applied to the liquid crystal cell and (ii) the residual DC voltage occurring after the voltage including a direct-current voltage component is applied to the liquid crystal cell,
the evaluation step includes:
a first estimation step of estimating, for the each of the predetermined plurality of temperatures, (a) an adsorption rate coefficient of ions that adsorb to an interface between the liquid crystal and one of the alignment films and (b) a desorption rate coefficient of ions that desorb from the interface, based on the plurality of combinations of the application time and the residual DC voltage at the each of the predetermined plurality of temperatures; and
a second estimation step of estimating an adsorption energy of the ions that adsorb to the interface, based on the adsorption rate coefficients of the predetermined plurality of temperatures, and a desorption energy of the ions that desorb from the interface, based on the desorption rate coefficients of the predetermined plurality of temperatures, and
the selecting step is a step of selecting the material of the liquid crystal and the material of the alignment films in accordance with the adsorption energy and the desorption energy each estimated in the evaluation step.

27. The manufacturing method as set forth in claim 25, wherein:
the measuring step is a step of measuring, at each of a predetermined plurality of temperatures, a time-dependence of the residual DC voltage that changes over time after the liquid crystal cell is caused to be open-circuit,
the evaluation step including:
a first estimation step of estimating, for the each of the predetermined plurality of temperatures, a first relaxation rate coefficient and a second relaxation rate coefficient from among a plurality of relaxation rate coefficients of ions relaxed from an interface between the liquid crystal and one of the alignment films, based on the time-dependence of the residual DC voltage that changes over time after the liquid crystal cell is caused to be open-circuit; and
a second estimation step of estimating a first relaxation energy based on the first relaxation rate coefficients of the predetermined plurality of temperatures, and a second relaxation energy based on the second relaxation rate coefficients of the predetermined plurality of temperatures, and
the selecting step is a step of selecting the material of the liquid crystal and the material of the alignment films in accordance with the first relaxation energy and the second relaxation energy each determined in the evaluation step.
